(19) United States
(12) Patent Application Publication
(10) Pub. No.: US 2010/0090230 A1
(43) Pub. Date: Apr. 15, 2010

(54) CRYSTAL SILICON ELEMENT AND METHOD FOR FABRICATING SAME

(76) Inventor: Hideo Honma, Osaka (JP)

Correspondence Address: BIRCH STEWART KOLASCH & BIRCH, PO BOX 747, FALLS CHURCH, VA, 22040-0747, US

(21) Appl. No.: 11/997,399

(22) PCT Filed: Aug. 1, 2006
(86) PCT No.: PCT/JP2006/315222

§ 371 Date: Jan. 30, 2008

(30) Foreign Application Priority Data
Aug. 5, 2005 (JP) 2005-228096
Aug. 5, 2005 (JP) 2005-228242
May 18, 2006 (JP) 2006-139004

(51) Int. Cl. H01L 33/00; H01L 21/18; H01L 21/28; H01L 29/40; H01L 29/12

(52) U.S. Cl. 257/89; 438/609; 438/694; 438/571; 257/485; 257/734; 438/509; 977/773; 257/E33.064; 257/E29.111; 257/E29.068; 257/E21.085; 257/E21.158

(57) ABSTRACT

It is an object of the present invention to provide a crystal silicon element emitting a desired visible light at high efficiency, by markedly enhancing the crystallinity of the nano Si. A p-type single crystal silicon substrate 10, a thick silicon oxide film 17a and a thin silicon oxide film 17b are disposed on the one surface of the silicon substrate 10. On the thin silicon oxide film 17b, plural nano Si 15 having the same crystal axis as the silicon substrate 10 are formed. In addition, a thin silicon oxide film 16 that is disposed in a manner that the thin silicon film 16 covers the upper and side faces of the nano Si 15, and a transparent electrode (for example ITO) 19 that is disposed in a manner that the transparent electrode 19 covers at least the upper face of the nano Si 15 are formed. Further, a metal electrode 18 (for example, aluminum) is formed in a manner that the metal electrode 18 has an ohmic contact with the other surface of the silicon substrate 10.

### TECHNICAL FIELD OF THE INVENTION

The present invention relates to a crystal silicon element and a method for fabricating the same, and more specifically, a crystal silicon element such as a light-emitting element configured by a nano crystal silicon element and the fabrication method thereof.

### BACKGROUND ART

Similarly to a current-controlled element that shifted from a vacuum tube to a solid-state semiconductor element, a lighting element has shifted rapidly in recent years from a fluorescent lamp to a solid-state light-emitting element such as a III-V group compound semiconductor. The solid-state light-emitting element will undoubtedly make continuous progress in the future.

However, a presently prevailing Ga-base compound semiconductor requires an epitaxial growth with minimum defects on an expensive sapphire substrate. In addition, a p-n junction or a quantum well structure is required to be formed. A complex multi-layered structure containing Al, P, In, N or the like is required. These requirements make it difficult to provide an inexpensive element.

In order to address the above problems, attempts have been made to provide an inexpensive light-emitting element using silicon (Si) that is the most abundant material on the earth. Si has been considered to be unsuitable as a visible light-emitting material because Si is an indirect band gap semiconductor having a low light emission efficiency, also because Si has a band gap in the near-infrared region.

However, for example, in Non-Patent Document 1, a porous Si formed by anodic oxidation was reported to have a capability of emitting visible light. Thereafter, nanometer-size crystalline Si (hereinafter, abbreviated as nano Si) has come to draw attention as a potential candidate for a visible light-emitting element.

The light emission from the nano Si is considered to be due to the quantum confinement effect (band gap expansion) that is induced by reducing nanometer-size Si crystals. For the realization of a nano Si light-emitting element, enhancing the light emission efficiency to a practical level is essential. The biggest challenge is in the improvement of crystallinity including the surface state. Further, in order to obtain a desired luminescent color, wavelength control is necessary, and also the crystal size of the nano Si should be regulated with high accuracy.

The porous Si obtained by using anodic oxidation as mentioned above is formed by eroding a Si surface into a porous state with a specific action of oxidation. For this reason, although the crystal itself has a relatively good quality, the surface area is quite large, and instability of the light-emitting properties is pointed out. In addition, the shape and morphology of the porous Si is hardly regulated, whereby the wavelength control is hardly expected.

As a countermeasure against the problems mentioned above, several methods have been proposed so far. For example, granular Si crystals are formed on a substrate by ion injection, sputtering, CVD (Chemical Vapor Deposition) or the like, and then the granular Si crystals are elaborately embedded in a stable material such as silicon oxide (SiO₂) (refer to Patent Document 1, Patent Document 2, and Patent Document 3).
Non patent document 1: L. T. Canham, Applied Physics Letters, 1990, Vol. 57, Page 1046
Patent document 1: Japanese Patent Application Laid Open Publication No. 8-17577.
Patent document 2: Japanese Patent Application Laid Open Publication No. 2004-296781.
Patent document 3: Japanese Patent Application Laid Open Publication No. 8-307011.

### DISCLOSURE OF THE INVENTION

### Problems to be Solved by the Invention

However, the aforementioned conventional methods all had a disadvantage in the uniformity of crystals because the objective product was formed by injecting or depositing Si or a Si compound. Therefore, the light-emitting elements based on the conventional methods had difficulty in emitting visible light at high efficiency.

The present invention has been made to address the aforementioned problems. It is an object of the present invention to provide a crystal silicon element emitting a desired visible light at high efficiency, by markedly enhancing the crystallinity of the nano Si, and a method for fabricating the crystal silicon element.

### Means for Solving the Problems

The present inventors have made intensive studies to meet the foregoing objective and found that increasing the crystallinity of the nano Si and controlling the crystal face orientation are essential for enhancing the light emission efficiency.

Namely, in the present invention, unlike the related arts in which the crystal axes are randomly oriented, the crystal axes of plural nano Si crystals formed on a substrate are oriented in the same direction so as to make the crystal face orientations uniform. In this way, the light emission efficiency is enhanced remarkably.

The mechanism is not clear, but the light emission efficiency became maximum when the face direction perpendicular to the flow line direction of carriers flowing into the nano Si is oriented to (100), followed by (110) and (111). The dangling bond density on the Si surface is ranked as (100), (110), and (111) in an ascending order, so that the presence of non light-emitting recombination centers due to the dangling bond density is considered to be one of the factors that determine the light emission efficiency. In order to attain a high light emission efficiency, it is desirable that the crystal face of the nano Si be oriented in the same direction and more preferably be regulated to (100).

Therefore, a first crystal silicon element of the present invention has a silicon substrate, a nanometer-size crystal silicon (nano Si) having the same crystal face orientation as the silicon substrate, further preferably, a metal electrode, and a transparent electrode that forms a pair of electrodes together with the metal electrode so as to sandwich the crystal silicon between the electrodes. In a configuration where plural nanometer-size crystal silicons having the same crystal face orientation and disposed on the same plane are sandwiched between a pair of electrodes, that is, between the transparent electrode and the metal electrode, carriers (electrons or holes) injected from the electrodes to the crystal silicon such as the nano Si recombine efficiently (enhancing quantum efficiency) at a light-emission center, so that the light emission efficiency may be remarkably enhanced. Further, in the case where the nano Si (crystal silicon) in the light-emitting layer is composed of the same material as the silicon substrate, the effect of strain caused by thermal expansion or the like may be desirably minimized, whereby stable light emission is expected.

Here, preferably, the metal electrode may have an ohmic contact with the other surface of the silicon substrate, and the transparent electrode may be disposed on the crystal silicon.

Further, the transparent electrode may preferably have a contact with the crystal silicon through an insulating film in which carriers are tunnel-injected, so that the nano Si may be protected by the stable insulating film, whereby still higher light emission efficiency and stabilization may be desirably attained.

Still further, the transparent electrode may preferably have a direct contact with the crystal silicon and form a Schottky junction, so that carriers may be injected at a lower voltage (enhancing injection efficiency) as compared with the case where the insulating film is interposed, whereby the power consumption of the resulting light-emitting element may be advantageously reduced.

Further, the crystal silicon may preferably have a crystal structure with a crystal face that intersects quasi-perpendicularly the flow line of the carriers injected and have at least any one of the orientations (100), (110), and (111). In this way, enhanced light emission efficiency and stability may be attained. Particularly preferable is a crystal structure with the (100) crystal face orientation.

Further, preferably, the crystal silicon may be disposed separately from the silicon substrate, and the silicon substrate and crystal silicon may contact each other through an insulating film into which carriers are easily injected. The surface of the crystal silicon may be protected by the stable insulating film, so that the surface recombination current of the carriers may be reduced, whereby still higher light emission efficiency and stabilization may be attained.

Still further, the silicon substrate and the crystal silicon may preferably contact each other at a contact face having a size smaller than the size of the crystal silicon, whereby a homo-junction is formed. Carriers may be injected at a lower voltage (enhancing injection efficiency) as compared with the case where the insulating film is interposed, so that the power consumption of the resulting light-emitting element may be reduced.

From another standpoint, a crystal silicon element to which the present invention is applied is provided with: a silicon substrate that has one surface and the other surface opposite to the one surface; a nanometer-size crystal silicon that is disposed on the one surface of the silicon substrate and has the same crystal face orientation as the silicon substrate; a transparent electrode that is formed on the one surface of the silicon substrate, the silicon substrate having the crystal silicon disposed on the one surface; and a metal electrode that is formed on the other surface of the silicon substrate.

Here, the crystal silicon may preferably have a quasi-columnar shape and a diameter of 4 nm or less reduced to a spherical particle. According to an experiment, the size at which the quantum confinement effect emerges and a visible light emission is obtained is about 4 nm or less, so that it is expected to attain light visible monochromatic to white at a high efficiency by controlling the size at 4 nm or less in various manners.

The variation of the diameter of the columnar nano Si reduced to a spherical particle may preferably be selected at 20% or less, so that any of red, green, and blue monochromatic light maybe emitted. For example, the half width of wavelength may be preferably narrow to the full extent in order to obtain a monochromatic light of three primary colors (red, green, blue), and monochromatic light having an extremely narrow wavelength may be emitted efficiently by limiting the size variation within 20% or less.

Still further, the crystal silicon may preferably be shaped in mixed sizes so as to emit red, green, and blue light, whereby a white light-emitting element having a high efficiency may be advantageously attained.

A first fabrication process of the present invention, that is, a method for fabricating the first crystal silicon element using the silicon microcrystals, includes the steps of: disposing, on one surface of a silicon substrate, plural nanometer-size crystal silicons having the same crystal face orientation as the silicon substrate in a manner that the crystal silicons are isolated from the substrate; disposing a transparent electrode on one surface of the silicon substrate; and disposing a metal electrode on the other surface of the silicon substrate. The nano Si crystal are isolated from a single crystal silicon substrate having excellent crystallinity, so that the nano Si having a uniform crystal face orientation may be disposed keeping good crystallinity. As a result, a highly efficient light-emitting element may be provided in a cost-effective manner. Note that, the metal electrode is desirably disposed in a manner that the metal electrode has an ohmic contact with the substrate.

The step of disposing the crystal silicon while being isolated from the silicon substrate may preferably include the steps of: coating nanometer-size particles dispersed on one surface of a single crystal silicon substrate; forming columnar protrusions by etching the one surface of the silicon substrate using the particles as a mask; and isolating the columnar protrusions from the silicon substrate by oxidizing the one surface except the columnar protrusions. The particles having a controlled particle size are used as the mask to etch the substrate and crystal silicons such as nano Si are cut out directly from the substrate, so that crystal silicons having excellent crystallinity, a uniform crystal face orientation and particle size may be formed with good reproducibility. As a result, a highly efficient light-emitting element having excellent controllability of emission wavelength may be provided with a high yield in a cost-effective manner.

The single crystal silicon substrate may have a three-layered structure of single crystal silicon thin film/insulating thin film/single crystal silicon (so called SOI (Silicon On Insulator) substrate) The nano Si crystals are cut out from a single crystal silicon thin film having a controlled thickness, so that the volume of the nano Si may be easily regulated. Namely, the middle layer serving as the insulating film works as a stopper for etching in the silicon etching step, so that the height of the Si columnar protrusions may be easily regulated. The planar shape is regulated by the nanometric particles serving as the etching mask, so that the volume of the nano Si is much more easily regulated and that the emission wavelength is still more easily regulated.

From another point of view, the first fabrication process of the present invention includes the steps of: disposing nanometric particles dispersedly disposed on the one surface of a single crystal silicon substrate; etching one surface of the single crystal silicon substrate using the nanometric particles as an etching mask; and removing the nanometric particles from the one surface of the single crystal silicon substrate. The first fabrication process may further include preferably the steps of: isolating the columnar protrusions from the silicon substrate by oxidizing the one surface except the columnar protrusions obtained in the etching step; disposing a transparent electrode on the one surface of the silicon substrate; and disposing a metal electrode on the other surface of the silicon substrate.

Next, a second crystal silicon element to which the present invention is applied is provided with: a n-type single crystal silicon substrate that has one surface and the other surface opposite to the one surface; and a nanometer-size p-type crystal silicon (nano Si) that is disposed on the one surface of the silicon substrate and has the same crystal face orientation as the silicon substrate.

Preferably, a metal electrode and a transparent electrode maybe further included. The transparent electrode forms a pair of electrodes together with the metal electrode. The p-type crystal silicon and the silicon substrate are sandwiched between the pair of electrodes.

Preferably, the metal electrode may be disposed on the other surface of the silicon substrate and has an ohmic contact with the silicon substrate, and the transparent electrode may be disposed on the p-type crystal silicon. The resulting configuration allows carriers (electrons/holes) that are injected from the electrodes into the p-type crystal silicon (nano Si) to recombine efficiently (enhancing quantum efficiency) at a light emission center, so that the light emission efficiency may be desirably remarkably enhanced. In addition, in the case where the nano Si in the light-emitting layer are composed of the same material as the silicon substrate, the effect of strain caused by thermal expansion or the like may be desirably minimized, whereby stable light emission is advantageously expected.

Further, preferably the transparent electrode may contact the p-type crystal silicon (nano Si) through a thin insulating film in which carriers are tunnel-injected, so that the surface of the nano Si is protected by the stable insulating film, whereby, for example, the light emission efficiency may be enhanced and stabilization may be attained because the surface recombination current that does not contribute to light emission may be reduced.

Still further, preferably the transparent electrode may have a direct contact with the p-type crystal silicon, so that the resulting p-n junction plane works as a hole barrier, whereby the light emission efficiency may be desirably enhanced. In addition, the nano Si and transparent electrode may preferably directly contact each other so as to provide a configuration where an ohmic contact with respect to holes is formed, so that carriers may be injected at a lower voltage (enhancing injection efficiency) as compared with the configuration where the insulating film is incorporated, whereby the power consumption of the resulting light-emitting element may be reduced.

Still further, the p-type crystal silicon may preferably have a crystal structure in which the crystal face quasi-perpendicular to the flow line of the carriers injected directs to (100), whereby the light emission efficiency may be advantageously enhanced because the non light-emission recombination caused by dangling bonds may be reduced.

Still further, the resistivity of the silicon substrate may preferably be 10 mΩcm or less, whereby high efficiency may be advantageously attained because the electron injection efficiency to the nanometer-size crystal silicon increases and the resistance loss at the silicon substrate accompanying the current flow may be reduced.

Still further, the p-type crystal silicon may preferably be doped with aluminum, whereby the light-emitting properties may be thermally stabilized because aluminum forms a deeper acceptor level than boron, which is a common p-type dopant.

From further point of view, a crystal silicon element to which the present invention is applied is provided with: a n-type single crystal silicon substrate that has one surface and the other surface opposite to the one surface; a nanometer-size p-type crystal silicon that is disposed on the one surface of the silicon substrate and has the same crystal face orientation as the silicon substrate; a transparent electrode that is formed on the one surface of the silicon substrate, the silicon substrate having the p-type crystal silicon disposed on the one surface; and a metal electrode that is formed on the other surface of the silicon substrate.

Further, in the crystal silicon element, the p-type crystal silicon and the transparent electrode contact each other through an insulating film, and a current flow passage is from the transparent electrode, through the insulating film, the p-type crystal silicon and the silicon substrate, to the metal electrode. The current flow passage is formed when a voltage is applied for carrier injection across two electrodes of the transparent electrode serving as an anode and the metal electrode serving as a cathode.

The p-type crystal silicon and the transparent electrode directly contact each other, and a current flow passage is from the transparent electrode, through the p-type crystal silicon and the silicon substrate, to the metal electrode. The current flow passage is formed when a voltage is applied for carrier injection across two electrodes of the transparent electrode serving as an anode and the metal electrode serving as a cathode.

A second fabrication process of the present invention, that is, a method of fabricating a second crystal silicon element using the silicon microcrystals, includes the steps of: disposing, on the one surface of a silicon substrate, plural nanometer-size p-type crystal silicons (nano Si) having the same crystal face orientation as the silicon substrate through solid-phase growth; disposing a transparent electrode on the one surface where the p-type crystal silicon are disposed; and disposing a metal electrode on the other surface of the silicon substrate. The nanometer-size crystal silicons having the same crystal face orientation as the silicon substrate may be formed at low temperatures through solid-phase epitaxial growth, so that no redistribution among p-type and n-type dopants occurs. The nanometer-size p-n junction may easily be formed with good reproducibility, whereby a highly efficient light-emitting element may be provided in a cost-effective manner.

Here, the p-type crystal silicon disposing process is provided with: a forming process that forms a thin film of aluminum-silicon (Al—Si) on the silicon substrate; a epitaxially-growing process that epitaxially grows in solid phase the p-type crystal silicon on the silicon substrate through heat treatment at a temperature not exceeding the melting point of the aluminum-silicon (Al—Si); and a removing process that removes the thin film of aluminum-silicon (Al—Si).

From furthermore point of view, the second fabrication process of the present invention includes the steps of: forming a thin film of aluminum-silicon (Al—Si) on one surface of a single crystal silicon substrate; growing the p-type crystal silicon (nano Si) on the silicon substrate by performing heat-treatment at a temperature not exceeding the melting point of the aluminum-silicon (Al—Si) and within a predetermined temperature range in which solid-phase epitaxial growth proceeds; and removing the thin film of aluminum-silicon (Al—Si). The second fabrication process may preferably further include the steps of: disposing a transparent electrode on one surface of the silicon substrate; and disposing a metal electrode on the other surface of the silicon substrate.

The predetermined temperature range in which the solid-phase epitaxial growth may proceed preferably has a lower limit of about 350° C. and an upper limit of about 550° C. not exceeding the melting point of 570° C. The Al—Si serves as a Si source for the solid-phase growth, so that the p-type nano Si auto-doped with Al may be easily formed with good reproducibility. In this way, a highly efficient light-emitting element may be provided in a cost-effective manner.

Next, a third crystal silicon element to which the present invention is applied is provided with: a single crystal silicon substrate that has a pair of surfaces; and a plurality of quasi-columnar crystal silicons (hereinafter, it may be called “nano Si column” for short) that are disposed on a principal surface of the single crystal silicon substrate, have the same crystal face orientation as the principal surface, and stand quasi-perpendicularly to the single crystal silicon substrate surface. Preferably, the crystal silicon element is provided with: a metal electrode; and a transparent electrode that forms a pair of electrodes together with the metal electrode. The pair of electrodes sandwiches the quasi-columnar crystal silicons.

Plural nano Si columns provided so as to stand quasi-perpendicularly on the same plane and have the same crystal face orientation with one another are sandwiched between a pair of electrodes, that is, between a transparent electrode and a metal electrode. Thus formed configuration allows carriers (electrons/holes) that are injected from the electrodes into the nano Si columns to recombine efficiently at light-emission centers (enhancing quantum efficiency), whereby the light emission efficiency may be remarkably enhanced. Further, in the case where the nano Si columns in the light-emitting layer are composed of the same material as the silicon substrate, the effect of strain caused by thermal expansion or the like may be desirably minimized, whereby stable light emission is preferably expected.

In the foregoing configuration, preferably, the metal electrode maybe disposed on the other surface of the single crystal silicon substrate and may have an ohmic contact with the single crystal silicon substrate, and the transparent electrode may be disposed so as to contact the upper face of the nano Si columns.

Further, the transparent electrode may preferably contact the nano Si columns through an insulating film in which carriers are easily tunnel-injected, so that the nano Si is desirably protected by the stable insulating film, whereby still more enhanced light emission efficiency and stability may be attained.

Still further, a Schottky junction may be preferably formed by allowing the transparent electrode to directly contact the quasi-columnar crystal silicons, so that carriers may be injected at a lower voltage (enhancing injection efficiency) as compared with the configuration in which the insulating film is incorporated. In this way, the power consumption of the resulting light-emitting element may be advantageously minimized.

Alternatively, the nano Si columns maybe preferably formed into a two-layered structure composed of a p-type conductive layer and an n-type conductive layer in the height direction, and one of the conductive layers has an ohmic contact with the transparent electrode. The carriers injected from the transparent electrode through one conductive layer to the other conductive layer recombine inside the nano Si columns, so that surface recombination that does not contribute to emission is reduced, whereby still more enhanced light emission efficiency and stability may be attained. Further, as compared with the configuration in which the insulating film is incorporated, carriers may be injected at a lower voltage (enhancing injection efficiency), so that the power consumption of the resulting light-emitting element may be advantageously reduced.

In the foregoing configuration, the bottom face of the nano Si columns may preferably contact directly the single crystal silicon substrate so as to form a homo-junction, and at least the side of the nano Si columns may be covered with an insulating film, so that the surface of the single crystal silicon substrate except the upper face of the nano Si columns is electrically insulated from the transparent electrode.

Still further, the nano Si columns may preferably have a crystal structure with a crystal face that intersects quasi-perpendicularly the flow line of the carriers injected and has at least any one of the orientations (100), (110), and (111). In this way, enhanced light emission efficiency and stability may be attained.

From furthermore point of view, a crystal silicon element to which the present invention is applied is provided with: a single crystal silicon substrate that has a pair of surfaces; a plurality of quasi-columnar crystal silicons (nano Si columns) that are disposed on a principal surface of the single crystal silicon substrate, have the same crystal face orientation as the principal surface, and stand quasi-perpendicularly to the single crystal silicon substrate surface; a transparent electrode that is formed on the principal surface of the single crystal silicon substrate having the nano Si columns and has a contact with the upper face of the nano Si columns, a metal electrode that is formed on the other surface of the single crystal silicon substrate.

Here, the nano Si column has a diameter of 4 nm or less and a column height 2 to 50 times of the diameter.

According to an experiment, the shape that allows the nano columns to exhibit the quantum confinement effect and to provide stable visible light emission should be characterized by a diameter of about 4 nm or less and a height of two or more times of the diameter. On the other hand, when the nano Si columns are exceedingly high, the light emission efficiency is lowered because the component of the resistance of the carriers injected from the silicon substrate into the nano Si columns and transported to the recombination region increases. The height of the nano Si columns is preferably within 50 times of the diameter. The diameter and height of the nano Si columns may be effectively controlled in various manners, so that light emission from visible monochromatic to white maybe attained at a high efficiency.

Still further, the nano Si columns may preferably be regulated in such a size that the Si columns may emit visible monochromatic light or white light. The nano Si columns may preferably be shaped in mixed sizes so as to emit red, green, and blue light, whereby a white light-emitting element having a high efficiency may be advantageously attained.

A third fabrication process of the present invention, that is, a method of fabricating a third crystal silicon element using the silicon microcrystals, includes the steps of: forming, on the principal surface of a silicon substrate, plural nano Si columns that have the same crystal face orientation as the silicon substrate and stand quasi-perpendicularly with respect to the principal surface of the silicon substrate by processing the silicon substrate; disposing, on the principal surface of the silicon substrate, a transparent electrode in a manner that the transparent electrode contacts the upper face of the nano Si columns; and disposing a metal electrode on the other surface of the silicon substrate.

The nano Si columns are formed by cutting out the single crystal silicon substrate having excellent crystallinity, so that nano Si having a uniform crystal face orientation may be formed while the excellent crystallinity is preserved. As a result, a highly efficient light-emitting element may be provided in a cost-effective manner.

Here, the nano Si columns disposing process is provided with: a thin film disposing process that disposes a thin film of aluminum on the principal surface of the single crystal silicon substrate;

a converting process that converts the thin film of aluminum into porous alumina having micropores with a uniform size through anodic oxidation; a embedding process that embeds an inorganic material in the micropores of the porous alumina; a removing process that selectively removes the porous alumina by etching; and a quasi-columnar protrusions disposing process that disposes quasi-columnar protrusions by etching the principal surface of the silicon substrate using the inorganic material as a mask.

Nano Si columns are cut out of the silicon substrate by using, as a mask for etching the silicon substrate, an inorganic material made of a porous alumina having micropores with a uniform diameter, whereby nano Si columns having excellent crystallinity and uniform diameter are obtained with good reproducibility. As a result, a highly efficient light-emitting element having an excellent controllability of emission wavelength may be preferably provided with a high yield.

Further, the step of forming the nano Si columns may preferably includes the steps of: disposing an organic film of a block copolymerized polymer on the principal surface of the silicon substrate; performing heat treatment of the organic film for phase separation; forming micropores uniform in size in the organic film by selective etching; embedding an inorganic material in the micropores of the organic film; and etching the organic film and the principal surface of the silicon substrate so as to form quasi-columnar protrusions. In this way, nano Si columns having uniform size may be formed with good reproducibility more easily as compared with the aforementioned method using the porous alumina.

Still another step may be preferably included, namely, oxidizing the surface of the silicon surface except at least the upper face of the nano Si columns, so that the diameter of the nano Si columns maybe regulated and that the silicon substrate and the side face of the nano Si maybe electrically isolated from the transparent electrode.

The diameter of the nano Si columns is decreased by oxidation after the nano Si columns having a diameter larger than a desired value are formed, so that fabrication advantages such as mechanical stabilization of the nano Si columns may be attained and that the emission wavelength may be regulated easily. In addition, the oxidation also helps to reduce fabrication cost because the portions other than the upper face of the nano Si columns are electrically isolated from the transparent electrode. As a result, a highly efficient light-emitting element having an excellent controllability of emission wavelength may be provided with a high yield in a cost-effective manner.

### Effect of the Invention

According to the present invention, a nano Si light-emitting element having an excellent crystallinity with fewer non light-emission recombination centers may be provided.

### BEST MODE FOR CARRYING OUT THE INVENTION

Best modes for carrying out the present invention (hereinafter called as exemplary embodiments) will be explained in detail below. Note that, the present invention is in no way limited to those exemplary embodiments, but may be embodied in various forms within the scope of the present invention. Further, the accompanying drawings are used to explain the exemplary embodiments of the present invention, and do not show the actual size.

### Exemplary Embodiment 1

FIG. 1 is a fragmentary cross sectional view of a nano Si light-emitting element in accordance with an exemplary embodiment of the aforementioned first crystal silicon element. FIG. 2 is a perspective view of the nano Si light-emitting element shown in FIG. 1. In FIG. 2, in order to help the understanding of a nano Si light-emitting element configuration, a part of the transparent electrode is cut out.

As shown in FIGS. 1 and 2, a nano Si light-emitting element serving as a crystal silicon element has a p-type single crystal silicon substrate 10 having a pair of principal surfaces and silicon oxide films 17 including a thick silicon oxide film 17a and a thin silicon oxide film 17b that are disposed on the one principal surface (on the one surface) of the silicon substrate 10. In addition, on the thin silicon oxide film 17b, plural nano Si 15 as plural crystal silicons having the same crystal face orientation as the silicon substrate 10 are formed. The plural nano Si 15 are cylindrical columnar protrusions formed on the thin silicon oxide film 17b. Further, on the one surface of the silicon substrate 10, a thin silicon oxide film 16 is disposed in a manner that the thin silicon oxide film 16 covers the upper and side faces of the nano Si 15, and a transparent electrode (for example ITO) 19 is disposed in a manner that the transparent electrode 19 covers at least the upper face of the nano Si 15. In place of the thin silicon oxide film 16, a silicon nitride film may be used. Further, on the other principal surface (on the other surface) of the silicon substrate 10, a metal electrode 18 (for example, aluminum) is formed in a manner that the metal electrode 18 has an ohmic contact with the other surface of the silicon substrate 10.

The nano Si light-emitting element having the aforementioned configuration operates as a visible light-emitting element when a voltage is applied across the transparent electrode 19 serving as a cathode and the metal electrode 18 serving as an anode.

FIG. 3 is a chart that shows a band structure and carrier flow directions for explaining the operation principle shown in FIGS. 1 and 2. As shown in FIG. 3, electrons that are tunnel-injected from the transparent electrode 19 through a SiO₂ barrier of the thin silicon oxide film 16 and holes that are tunnel-injected from the metal electrode 18 via the silicon substrate 10 through the SiO₂ barrier of the thin silicon oxide film 17b are trapped at recombination centers inside the nano Si 15, and emit light. The reason why silicon having a near-infrared band gap emits visible light is due to the quantum confinement effect (band gap expansion) induced by reducing the crystal size. Namely, the nano Si light-emitting element having the aforementioned configuration is characterized in that various wavelength components may be attained by regulating the size of the nano Si 15. According to the investigational results in the present exemplary embodiment, blue color was obtained at a diameter of about 2 nm, green color at about 2.5 nm, and red color at about 3.3 nm (described later). Here, the diameter of the nano Si 15 is represented by being reduced to a spherical body. Therefore, in order to eliminate useless infrared light and attain a highly efficient visible light-emitting element, the nano Si 15 is required to have a diameter (reduced to a spherical body) of 4 nm or less, particularly to be regulated at from 2 nm to 4 nm. It is desirable that the variation of the diameter is regulated within 20% or less so as to obtain a monochromatic light such as three primary colors at a high efficiency.

The relationship between light emission efficiency and crystal axis of the nano Si 15 has been investigated in detail. The results of investigation show that the nano Si 15 having a uniform crystal face orientation according to the present exemplary embodiment provided remarkably enhanced light emission efficiency as compared with the related arts where randomly oriented crystal axes are involved. Further, in relation to the crystal face orientation of the upper face (the face directing quasi-perpendicularly to the flow direction of carriers) of the nano Si 15, the light emission efficiency reached a maximum at a crystal structure of (100) followed by (110) and (111). The relation with the crystal face orientation is in the reverse order with the dangling bond density, so that the dangling bonds on the nano Si surface are considered to work as recombination centers for non light-emission. Therefore, it is desirable that the upper face of the nano Si 15 be regulated to direct to the (100) face.

FIG. 4 is a fragmentary cross sectional view of a modified example of the nano Si light-emitting element shown in FIG. 1. In order to avoid explanation repetition, the portions that differ from the example shown in FIG. 1 are explained. In the modified example shown in FIG. 4, the thin silicon oxide film 16 disposed on the upper face of the nano Si 15 is eliminated so as to directly contact the nano Si 15 and the transparent electrode 19 and to form a Schottky junction 21. Namely, in the example shown in FIG. 1, electrons are injected from the transparent electrode 19 to the nano Si 15 by tunnel-injection through the insulating film barrier of the thin silicon oxide film 16. On the other hand, in the modified example shown in FIG. 4, electrons are injected from the transparent electrode 19 into the nano Si 15 by tunnel-injection through the Schottky barrier of the Schottky junction 21. In the Schottky junction 21, the transparent electrode 19 and the nano Si 15 contact each other and provide a rectification property similar to a p-n junction. The Schottky junction 21 may lower the barrier height as compared with the thin silicon oxide film 16. As a result, electron injection efficiency may be enhanced and the operation voltage may be lowered, whereby the power consumption of the nano Si light-emitting element may be reduced.

FIG. 5 is a fragmentary cross sectional view of another modified example of the nano Si light-emitting element shown in FIG. 1. In order to avoid explanation repetition, the portions that differ from the example shown in FIG. 1 are explained. In the modified example shown in FIG. 5, at the center of the position where the nano Si 15 is disposed, there is no thin silicon oxide film 17b that is shown in FIG. 1. Namely, in the example shown in FIG. 5, a direct contact between the single crystal silicon substrate 10 and the nano Si 15 is given with a smaller contact area as compared with the size of the nano Si 15 so as to develop a Si-Si homo-contact 20. The direct contact with a smaller contact area as compared with the size of the nano Si 15 hardly impairs the quantum confinement effect (band gap expansion) even the direct contact develops in the Si-Si homo-contact 20.

FIG. 6 is a chart that shows a band structure and carrier flow directions for the purpose of explaining the operation principle of the modified example shown in FIG. 5. In the example shown in FIG. 6, similarly to the aforementioned example, electrons are injected from the transparent electrode 19 to the nano Si 15 by tunnel-injection through the insulating film barrier (SiO₂ barrier) of the thin silicon oxide film 16. On the other hand, a small hole barrier is set up between the silicon substrate 10 and the nano Si 15, however, the hole barrier is lower as compared with the case where the thin silicon oxide film 17b is disposed, so that holes may be injected into the nano Si by applying a smaller bias voltage Therefore, the hole injection efficiency is enhanced, and the operation voltage is lowered. Namely, the power consumption of the nano Si light-emitting element may be reduced.

A nano Si light-emitting element may also be provided by combining the example shown in FIG. 4 and the example shown in FIG. 5. Specifically, the transparent electrode 19 is allowed to contact directly the nano Si 15 and the silicon substrate 10 is also allowed to directly contact the nano Si 15. This combination also may exert the effect of the present exemplary embodiment.

Here, there is mentioned the relationship between the size of the nano Si light-emitting element and the emission wavelength. FIG. 7 is a graph showing the relationship between the size of the nano Si and the peak value of emission wavelength obtained by a nano Si light-emitting element. The horizontal axis of FIG. 7 represents the diameter (nm) of the nano Si reduced to a spherical body and the vertical axis represents the peak wavelength (nm) of light emission. The experimental results are represented by a dotted line. According to the experimental results, when the diameter of the nano Si 15 is represented by being reduced to a spherical body as mentioned above, blue color was obtained at a diameter of about 2 nm, green color at about 2.5 nm, and red color at about 3.3 nm. Therefore, in order to eliminate useless infrared light and to attain a highly efficient visible light-emitting element, the diameter (reduced to a spherical body) of the nano Si 15 is required to be 4 nm or less and is preferably controlled to be 2 to 4 nm. Particularly, the variation of the diameter is desirably regulated within 20% or less in order to obtain monochromatic light such as three primary colors in high efficiency.

FIG. 8 shows still another modified example in the exemplary embodiment 1, showing a fragmentary cross sectional view of a white color nano Si light-emitting element. The nano Si light-emitting element of the modified example shown in FIG. 8 has a p-type single crystal silicon substrate 10 having a pair of principal surfaces and silicon oxide films 17 including a thick silicon oxide film 17a and a thin silicon oxide film 17b that are disposed on one principal surface (on one surface). In addition, on the thin silicon oxide film 17b, plural nano Si 15 as plural crystal silicons having the same crystal face orientation as the silicon substrate 10 are formed. The plural nano Si 15 are cylindrical columnar protrusions that are divisionally disposed on the thin silicon oxide film 17b in a manner that these protrusions are classified into three sizes of 15a, 15b, and 15c (L1, L2, and L3) so as to emit at least three colors of red, green and blue. Further, on one surface of the silicon substrate 10, a thin silicon oxide film 16 is disposed so as to cover the upper and side faces of the nano Si 15, and a transparent electrode (for example ITO) 19 is disposed so as to cover at least the upper face of the nano Si 15. In place of the thin silicon oxide film 16, a silicon nitride film may be used. Further, on the other principal surface (on the other surface) of the silicon substrate 10, a metal electrode 18 (for example, aluminum) is formed so as to make an ohmic contact with the other surface of the silicon substrate 10. In the example of FIG. 8, a light-emitting element emitting white color light may be easily attained by only divisionally disposing the nano Si 15 by classifying the size into at least three kinds. There is not any limitation on the pattern at which the three kinds of nano Si are disposed, but each color may be disposed linearly, blocked, or randomly so as to emit white color as a whole.

Next, a method of fabricating or producing a nano Si light-emitting element according to the exemplary embodiment 1 will be explained.

FIG. 9-1 and FIG. 9-2 are fragmentary cross sectional views illustrating a method of producing a nano Si light-emitting element according to the exemplary embodiment 1. The method is illustrated in the order of production steps. In this method, a single crystal silicon substrate 10 having a pair of (100) principal surfaces is prepared first, and a silicon nitride film 11 is formed on one principal surface (on one surface) by the CVD (Chemical Vapor Deposition) method (FIG. 9-1A).

Next, nano particles 12 including, for example, magnetite (Fe₃O₄) fine particles 12a having a diameter of 3 nm and protective organic groups 12b around the fine particles 12a are coated and dispersed on the silicon nitride film 11 (FIG. 9-1B). By using the nano particles 12 as a mask, the upper layer (for example, up to 3 nm deep) of the silicon nitride film 11 and the silicon substrate 10 are etched by the conventional RIE so as to form silicon protrusions 13a and depressions 13b (FIG. 9-1C).

Thereafter, the nano particles 12 are removed by wet process using an organic solvent, and a silicon nitride film 14 is formed on the entire surface by the conventional CVD method (FIG. 9-1D).

Next, the silicon nitride film 14a except the portion thereof on the side faces of the silicon protrusions 13a is removed by etching in the height direction of the silicon protrusions 13a using the RIE (Reactive Ion Etching) process (FIG. 9-2E).

Subsequently, by using the silicon nitride films 11 and 14a as a protection mask, a relatively thick silicon oxide film 17a as the silicon oxide film 17 is formed through heat treatment in an oxidative atmosphere. At this time, an appropriate control of the oxidation conditions allows the silicon oxide film to intrude beneath the silicon protrusions 13a (forming so called bird's beak), whereby the nano Si 15 isolated by a thin silicon oxide film 17b are formed (FIG. 9-2F).

Then, after the silicon nitride films 11 and 14a are removed by wet-etching process using hot phosphoric acid or the like, a thin silicon oxide film 16 having a controlled thickness is formed on the surface of the nano Si 15 through heat treatment in an oxidative atmosphere (FIG. 9-2G).

Finally, a transparent electrode (ITO) 19 composed of a compound based on indium oxide is formed on one principal surface (on the one surface) having the nano Si. A metal electrode 18 of aluminum is formed on the opposite surface (on the other surface) (FIG. 9-2H). In this way, a nano Si light-emitting element as shown in FIG. 1 is obtained.

The nano Si light-emitting element fabricated in the aforementioned process included the columnar nano Si 15 having a diameter of about 2.5 nm and a height of about 3 nm, and was confirmed to emit green color light having a peak wavelength of about 550 nm. The nano Si light-emitting element attained a remarkably enhanced light emission efficiency because of the following reasons.

Firstly, the nano Si 15 of the nano Si light-emitting element has the same crystal face orientation as the single crystal silicon substrate 10 and a uniform crystal face orientation of (100) as well, so that the number of the non light-emission recombination centers due to the dangling bonds on the surface of the nano Si may be minimized. In addition, the nano Si 15 may have a crystallinity almost free of defects because the nano Si 15 is cut out of the silicon substrate 10 having an extremely excellent crystallinity.

Further, a nano Si light-emitting element having an excellent uniformity in size may be formed because the size of the nano Si 15 is regulated by using the nano particles 12 having a uniform particle size as an etching mask. For this reason, an extremely excellent controllability of emission wavelength is attained. According to an experiment, the variation in the size was suppressed within 20% or less.

Still further, by changing the size of the nanoparticles 12, an element having a different emission wavelength may be easily produced in the similar production process. According to an experiment, when the size of the nano Si 15 is represented by a diameter reduced to a spherical body, blue color light was emitted at a diameter of about 2 nm, green color at about 2.5 nm, and red color at about 3.3 nm. A mixture thereof was confirmed to provide white color. In this way, according to the exemplary embodiment 1, a nano Si light-emitting element having a desired wavelength may be attained with a high yield in a cost-effective manner.

As the nanoparticles, magnetite (Fe₃O₄) was exemplified, but the other ferrite particles, or metal particles such as Au, Pt, Pd, Co, and the like may be used. Any material maybe used without limitation as long as the material works as an etching mask for the silicon substrate. Further, as the method of dispersedly disposing the nano particles, the method of coating nano particles having protective organic groups was exemplified, but there may be used, for example, a method of sputtering the aforementioned metal particles themselves. Furthermore, there maybe used a method of using a LB (Langmuir Blodgett) film or the like, or a method of using phase separation of a block copolymerized polymer or the like. Further, as the transparent electrode 19, ITO was exemplified, but any material may be used without any particular limitation as long as the material keeps transparency to visible light and possesses electrical conductivity. Further, as the metal electrode 18, aluminum was exemplified, but any material may be used without any particular limitation as long as the material is excellent in electrical conductivity and makes an ohmic contact with the silicon substrate. Still further, as the best mode of the crystal face orientation of the nano Si 15, (100) was exemplified, but (110) or (111) may also be used.

The completed form of the light-emitting element of the production method shown in FIGS. 9-1 and 9-2 was exemplified by the same nano Si light-emitting element as the one shown in FIG. 1, but maybe modified in various manners. For example, after the step of FIG. 9-2G, the thin silicon oxide film 16 on the upper face of the nano Si 15 may be removed by etching using the RIE process so as to lead to an embodiment of the modified example shown in FIG. 4. Further, the conditions for forming the thin silicon oxide film 17b as shown in FIG. 9-2F may be selected so as to lead to an embodiment in which the silicon substrate 10 and the nano Si 15 partly contact each other, that is, an embodiment of the modified example shown in FIG. 5. A combination of these embodiments may of course be included.

FIG. 10-1 and FIG. 10-2 are fragmentary cross sectional views illustrating another method of producing a nano Si light-emitting element according to the exemplary embodiment 1. The method is illustrated in the order of production steps. In this method, a so-called SOI (Silicon on Insulator) substrate 30 formed by a single crystal silicon substrate 30a, a silicon oxide thin film 30b and a single crystal silicon thin film 30c is prepared first, and a silicon nitride film 31 is formed on the single crystal silicon thin film 30c (FIG. 10-1A).

Next, nano particles 32 including magnetite (Fe₃O₄) fine particles 32a controlled a diameter of 3 nm and protective organic groups 32b around the particles are coated and dispersedly disposed on the silicon nitride film 31 (FIG. 10-1B).

By using the nano particles 32 as a mask, the silicon nitride film 31 and the single crystal silicon thin film 30c are etched by the RIE process so as to form nano Si 33 separated each other (FIG. 10-1C).

Next, after nano particles 32 are removed by wet process using an organic solvent, silicon oxide films 34 and 35 are formed through heat treatment in an oxidative atmosphere on the upper surface of the single crystal silicon substrate 30a and the side faces of the nano Si 33 (FIG. 10-2D).

Thereafter, a silicon nitride film 31 is selectively removed by dipping in hot phosphoric acid (FIG. 10-2E).

Finally, a transparent electrode (ITO) 36 composed of a compound based on indium oxide was formed on the principal surface (including on the nano Si 33) having the nano 33 disposed thereon, and a metal electrode 37 of aluminum is formed on the other surface so as to obtain a nano Si light-emitting element (FIG. 10-2F).

The nano Si light-emitting element obtained as described above includes columnar nano Si having a diameter of about 2 nm and a height of about 2.5 mm, and was confirmed to emit blue color light having a peak wavelength of about 440 nm by applying a voltage across the transparent electrode 36 serving as a cathode and the metal electrode 37 serving as an anode. In the product element provided by the production method shown in FIG. 10-1 and FIG. 10-2, a silicon oxide thin film 30b and a single crystal silicon thin film 30c have an excellent controllability of thickness, so that the nano Si 33 may acquire an enhanced precision in height as compared with the aforementioned production method shown in FIG. 9-1 and FIG. 9-2. In addition, hole injection from the single crystal silicon substrate 30a into the nano Si 33 may be stabilized at low voltage. Further, the diameter of the columnar nano Si 33 maybe controlled by the thickness of the oxide film formed in the thermal oxidation step, so that three primary colors of red, green, and blue may be separately formed in the same procedure. Therefore, a highly efficient light-emitting element having an excellent controllability in emission wavelength may be provided in a cost-effective manner.

In this way, as mentioned above in detail, according to the exemplary embodiment 1, crystal silicons such as the nano Si have a uniform crystal face orientation and the nano Si is directly cut out of the silicon substrate of single crystal by using the nano particles so that a nano Si light-emitting element having a high quality crystal (high efficiency) with reduced number of non light-emission recombination centers and an excellent controllability in particle diameter (controllability in emission wavelength) may be attained. As a result, there may be provided in a cost-effective manner, a long-life, highly efficient nano Si light-emitting element emitting any light freely from three principal colors to white color.

### Exemplary Embodiment 2

FIG. 11 is a fragmentary cross sectional view of a nano Si light-emitting element in accordance with an exemplary embodiment of the aforementioned second crystal silicon element. As shown in FIG. 11, the nano Si light-emitting element serving as a crystal silicon element has a n-type single crystal silicon substrate 40 having a pair of principal surfaces, silicon oxide films 43 disposed on the one principal surface (one surface side) of the silicon substrate 40 and having an aperture portion partly, and plural nano Si (p-type crystal silicon) 42 disposed on the aperture portion of the silicon oxide films 43 and having the same crystal face orientation as the silicon substrate 40. Further, the nano Si light-emitting element has a silicon oxide films 44 disposed in a manner that the silicon oxide film 44 covers the upper and side faces of the nano Si 42, and a transparent electrode (for example ITO) 45 disposed in a manner that the transparent electrode 45 covers at least the upper face of the nano Si 42. Furthermore, on the other principal surface (on the other surface) of the silicon substrate 40, a metal electrode 46 (for example, aluminum) is formed in a manner that the metal electrode 46 has an ohmic contact with the other surface of the silicon substrate 40.

The nano Si light-emitting element having the above configuration is operated as a visible light-emitting element by applying a voltage across the transparent electrode 45 serving as an anode and the metal electrode 46 serving as a cathode. When a voltage is applied across the two electrodes of the transparent electrode 45 serving as an anode and the metal electrode 46 serving as a cathode, a current flows along the following pathway: from the transparent electrode 45, through the insulating film (silicon oxide film 44), the p-type crystal silicon (nano Si 42) and the silicon substrate 40, to the metal electrode 46.

FIG. 12 is a chart that shows a band structure and carrier flow directions for explaining the operation principle shown in FIG. 11. As shown in FIG. 12, holes that are tunnel-injected from the transparent electrode 45 through the thin silicon oxide film 44 and electrons that are injected from the metal electrode 46 via the single crystal silicon substrate 40 through a p-n junction are trapped at recombination centers inside the nano Si 42, and emit light. The reason why silicon having a near-infrared band gap emits visible light is due to the quantum confinement effect (band gap expansion) induced by reducing the crystal size. Since the p-n junction between the nano Si 42 and the silicon substrate 40 serves as a hole barrier, the quantum confinement effect is not spoiled. That is, it is not necessary to cover the nano Si 42 with the silicon oxide film like a conventional method, and light emission efficiency may be increased.

The nano Si light-emitting element having the aforementioned configuration is characterized in that various wavelength components may be attained by regulating the size of the nano Si 42. According to the result of the study in the present exemplary embodiment, when the diameter of the nano Si 42 is represented by being reduced to a spherical body, blue color was obtained at a diameter of about 2 nm, green color at about 2.5 nm, and red color at about 3.3 nm. Therefore, in order to eliminate useless infrared light and to attain a highly efficient visible light-emitting element, the diameter (reduced to a spherical body) of the nano Si 42 is required to be 4 nm or less and is preferably controlled to be 2 to 4 nm.

The relationship between light emission efficiency and crystal axis of the nano Si 42 has been investigated in detail. The results of investigation show that the nano Si 42 having a uniform crystal face orientation according to the present exemplary embodiment provided remarkably enhanced light emission efficiency as compared with the related arts where randomly oriented crystal axes are involved. Further, in relation to the crystal face orientation of the upper face (the face directing quasi-perpendicularly to the flow direction of carriers) of the nano Si 42, the light emission efficiency reached a maximum at a crystal structure of (100) followed by (110) and (111). The relation with the crystal face orientation is in the reverse order with the dangling bond density, so that the dangling bonds on the nano Si surface are considered to work as recombination centers for non light-emission. Therefore, it is desirable that the upper face of the nano Si 42 be regulated to direct to the (100) face.

FIG. 13 is a fragmentary cross sectional view of a modified example of the nano Si light-emitting element shown in FIG. 11. In order to avoid explanation repetition, the portions that differ from the example shown in FIG. 11 are explained. In the modified example shown in FIG. 13, the thin silicon oxide film 44 disposed at least on the upper face of the nano Si 42 is eliminated so as to directly contact the nano Si 42 and the transparent electrode 45 and to form an ohmic contact. Namely, it is the same as the example shown in FIG. 11 except electrons being injected from the transparent electrode 45 to the nano Si 42 by tunnel-injection through the Schottky barrier (ohmic contact) instead of the insulating film barrier.

As described above, in the example of FIG. 13, the transparent electrode 45 and the nano Si 42 serving as a p-type crystal silicon are in direct contact with each other, and when a voltage is applied across the two electrodes of the transparent electrode 45 serving as an anode and the metal electrode 46 serving as a cathode to inject carriers, a current flows along the following pathway: from the transparent electrode 45, through the p-type crystal silicon (nano Si 42) and the silicon substrate 40, to the metal electrode 46.

FIG. 14 is a chart that shows a band structure and carrier flow directions for the purpose of explaining the operation principle of the modified example shown in FIG. 13. The ohmic contact thus formed has an advantage of lowering and stabilizing the barrier as compared with the case where the silicon oxide film 44 is disposed as in the example shown in FIG. 12. In other word, the barrier height may be kept constant regardless of the thickness. As a result, the operation voltage may be lowered by enhancing the hole injection efficiency, namely, the power consumption of the nano Si light-emitting element may be reduced.

Hereinafter, a method of producing a nano Si light-emitting element according to the present exemplary embodiment will be explained. FIGS. 15-1 and 15-2 are fragmentary cross sectional views illustrating a method of producing a nano Si light-emitting element according to the exemplary embodiment 2. The method is illustrated in the order of production steps. In this method, prepared first is a silicon substrate 40 of an n-type single crystal containing a high concentration of phosphorus (P), on a pair of principal surfaces having a (100) face. An Al and Si alloy film 41 containing 1 wt % Si is formed on one principal surface (on one surface) by the sputtering method (FIG. 15-1A).

Next, by heating at about 450° C. in a hydrogen atmosphere, a nano Si 42 having the same crystal face orientation as the single crystal silicon substrate 40 is formed through solid phase epitaxial growth on the single crystal silicon substrate 40 (FIG. 15-1B). Because the melting point of the aluminum-silicon (Al—Si) is about 570° C., a temperature of about 450° C. was selected as a predetermined temperature not exceeding the melting point. The current study made by the present inventors shows that about 350° C. is desirable as the lower limit of the predetermined temperature at which the solid phase epitaxial growth proceeds and that about 550° C. is desirable as the upper limit of the predetermined temperature. The extent of the growth may be controlled by regulating the annealing temperature and time.

Thereafter, through etching with hot phosphoric acid, unnecessary portions of the Al and Si alloy film 41 are removed (FIG. 15-1C).

Next, through heat treatment in an oxidative atmosphere containing water vapor, a thick silicon oxide film 43 is formed on the single crystal silicon substrate 40, and a thin silicon oxide film 44 is formed on the nano Si 42 (FIG. 15-2D). In this step, a phenomenon of enhanced oxidation rate of silicon containing high concentration of P is used.

Finally, on one principal surface (on the one surface) having the nano Si 42 disposed thereon, a transparent electrode (ITO) 45 composed of a compound based on indium oxide is formed, and on the opposite surface (on the other surface), a metal electrode 46 of aluminum is formed (FIG. 15-2E).

A nano Si light-emitting element prepared through the aforementioned series of steps was confirmed to work as an EL element having the transparent electrode 45 serving as an anode and the metal electrode 46 serving as a cathode and to emit visible light at a high efficiency. The light emission efficiency of the nano Si light-emitting element has been remarkably enhanced due to the following reasons. Firstly, the nano Si 42 has the same crystal face orientation as the single crystal silicon substrate 40 and has a uniform crystal face orientation of (100), so that the number of the non light-emission recombination centers due to dangling bonds on the surface of the nano Si 42 may be minimized.

In addition, the nano Si 42 is prepared from the excessive Si of the Al and Si alloy film 41 by epitaxial growth, so that the nano Si 42 is given as a p-type crystal that contains Al atoms autodoped therein. In this way, a p-n junction having a nanometer-size contact face is formed between the p-type crystal and the n-type single crystal silicon substrate 40. The p-n junction surface works as a hole barrier, so that the light emission efficiency of the nano Si light-emitting element may be enhanced.

According to the production method shown in FIGS. 15-1 and 15-2, the size of the nano Si 42 may be changed freely by regulating the temperature and time of annealing in the solid phase growth and the ratio of Si contained in the Al—Si alloy. Namely, light-emitting elements having a different emission wavelength from each other may be easily produced in the similar production process. In this way, a nano Si light-emitting element having a desired wavelength may be produced with a high yield in a cost-effective manner.

The completed form of the crystal silicon light-emitting element of the production method shown in FIGS. 15-1 and 15-2 is exemplified by the same one shown in FIG. 11, but may be modified in various manners. For example, after the step of FIG. 15-2D, the silicon oxide film 44 on the upper face of the nano Si 42 may be removed by etching using the RIE (Reactive Ion Etching) process so as to lead to an embodiment of the modified example shown in FIG. 13

As the transparent electrode 45, ITO (Indium Tin Oxide) is exemplified, but any material may be used without any particular limitation as long as the material keeps transparency to visible light and possesses electrical conductivity. As the metal electrode 46, aluminum is exemplified, but any material may be used without any particular limitation as long as the material is excellent in electrical conductivity and makes an ohmic contact with the silicon substrate 40. Further, as a dopant of the n-type single crystal silicon substrate 40, phosphorus (P) is exemplified, but arsenicum (As), antimony (Sb) or the like may be acceptable. From a point of view of reducing the resistance loss when current is applied, for the n-type single crystal silicon substrate 40, it is necessary to be as thinner as possible and have lowest possible electric resistivity. It is desirable to be 10 mΩcm or less for practical purposes.

FIG. 16-1 and FIG. 16-2 are fragmentary cross sectional views illustrating another method of producing a nano Si light-emitting element in the order of production steps according to the exemplary embodiment 2. The n-type single crystal silicon substrate 40 having a pair of principal surfaces formed by (100) face and including high level of As is prepared first, and a silicon nitride film 50 is formed on one principal surface by the CVD (Chemical Vapor Deposition) method (FIG. 16-1A).

Next, nano particles 51 including, for example, magnetite (Fe₃O₄) fine particles 51a having a diameter of 5 nm and protective organic groups 51b around the fine particles 51a are coated and dispersed on the silicon nitride film 50 (FIG. 16-1B).

By using the nano particles 51 as a mask, the silicon nitride film 50 is etched by the RIE process so as to form a silicon nitride film 50a to be patterned (FIG. 16-1C).

Thereafter, the nano particles 51 are removed by wet process using an organic solvent, and heat treatment is performed under the oxidizing atmosphere while a silicon nitride film 50a serves as a oxidization protection mask. Further, the remaining silicon nitride film 50a is removed by soaking in the heated phosphoric acid solution and a thick silicon oxidized film 43 is formed and an aperture portion 52 having a diameter of 4 nm or less is also formed (FIG. 16-1D).

Next, an Al and Si alloy film 41 including 1.5 wt % Si is formed by the sputtering method (FIG. 16-2E). Then, by performing heat treatment at approximately 480° C. under the hydrogen atmosphere, a nano Si 42 having the same crystal face orientation as that of the silicon substrate 40 is selectively and solid-phase epitaxially grown on the aperture portion 52 of the silicon oxidized film 43 on the single crystal silicon substrate 40 (FIG. 16-2F).

Thereafter, by performing etching processing with heated phosphoric acid, unnecessary Al and Si alloy film 41 is removed (FIG. 16-2G).

Finally, by forming the transparent electrode (ITO) 45 composed of a compound based on indium oxide on one principal surface (on the one surface) having the nano Si 42, and the metal electrode 46 of aluminum on the opposite surface (on the other surface), a nano Si light-emitting element is obtained (FIG. 16-2H).

The nano Si light-emitting element obtained as described above includes columnar nano Si 42 having a diameter of about 2.5 nm, and is confirmed to emit green color light having a peak wavelength of about 550 nm by applying a voltage across the transparent electrode 45 serving as an anode and the metal electrode 46 serving as a cathode. In the present exemplary embodiment, since a size of the aperture portion 52 of the silicon oxide film 43 is controlled with high precision by the size of the nano particle 51, uniformity of the particle diameter size of the nano Si 42 that selectively grows on the aperture portion 52 is remarkably improved. Further, the diameter of the nano Si 42 may be controlled by controlling the diameter of the nano particle 51 and the oxidization condition of the silicon oxidized film 43, so that three primary colors of red, green, and blue may be separately formed in the same procedure. Therefore, a highly efficient light-emitting element having an excellent controllability in emission wavelength may be provided in a cost-effective manner.

As the nano particles, magnetite (Fe₃O₄) is exemplified, but the other ferrite particles, or metal particles such as Au, Pt, Pd, Co, and the like may be used. Any material may be used without limitation as long as the material works as an etching mask for the silicon nitride film. Further, as the method of dispersing the nano particles, the method of coating nano particles having protective organic groups is exemplified, but there maybe used, for example, a method of sputtering the metal particles directly. Furthermore, there may be used a method of using a LB (Langmuir Blodgett) film or the like, or a method of using phase separation of a block copolymerized polymer or the like.

In this way, as mentioned above in detail, according to the exemplary embodiment 2, a p-type conductive nano size crystal silicons having the same crystal face orientation as the n-type conductive silicon substrate are provided on the n-type conductive silicon substrate, so that a nano Si light-emitting element having a high quality crystal with reduced number of non light-emission recombination centers may be attained. As a result, there may be provided, in a cost-effective manner, a long-life and highly efficient nano Si light-emitting element.

### Exemplary Embodiment 3

FIG. 17 is a fragmentary cross sectional view that illustrates a nano Si light-emitting element in accordance with an exemplary embodiment of the aforementioned third crystal silicon element. FIG. 18 is a perspective view that illustrates the nano Si light-emitting element shown in FIG. 17. In FIG. 18, in order to help the understanding of a nano Si light-emitting element configuration, a part of the transparent electrode is cut out.

As shown in FIGS. 17 and 18, a nano Si light-emitting element serving as a crystal silicon element has a p-type single crystal silicon substrate 60 formed by a single crystal having a pair of surfaces (in FIG. 17, described as “single crystal Si substrate”) and plural nano Si columns 66 having the same crystal face orientation as the single crystal silicon substrate 60 on one surface (principal surface) side of the single crystal silicon substrate 60.

The nano Si column 66 is indirect contact with single crystal silicon substrate 60 to form a homo junction, and is a cylindrical columnar protrusion quasi-perpendicular to the principal surface of the single crystal silicon substrate 60. Further, on the principal surface of the single crystal silicon substrate 60, a thick silicon oxide film 67 is disposed on an area except the upper faces of the nano Si columns 66, and a transparent electrode (for example ITO) 69 is disposed so as to cover the thick silicon oxide film 67 and the upper faces of the nano Si columns 66. On the other principal surface (on the other surface) of the single crystal silicon substrate 60, a metal electrode 68 (for example, aluminum) is formed in a manner that the metal electrode 68 has an ohmic contact with the single crystal silicon substrate 60.

The nano Si light-emitting element having the aforementioned configuration operates as a visible light-emitting element when a voltage is applied across the transparent electrode 69 serving as a cathode and the metal electrode 68 serving as an anode.

It should be noted that, the thickness of the thick silicon oxide film 67 is generally about 5 nm to about 50 nm, and is preferably about 10 nm to about 30 nm.

FIG. 19 is a chart that shows a band structure and carrier flow directions for explaining the operation principle shown in FIGS. 17 and 18. As shown in FIG. 19, electrons that are injected from the transparent electrode 69 through a Schottky barrier to the nano Si column 66 and holes that are injected from the metal electrode 68 (refer to FIG. 17) via the single crystal silicon substrate 60 to the nano Si column 66 are trapped at recombination centers inside the nano Si column 66, and emit light.

The reason why silicon having a near-infrared band gap emits visible light is due to the quantum confinement effect (band gap expansion) induced by reducing the crystal size (diameter of the column). Namely, the nano Si light-emitting element having the aforementioned configuration is characterized in that various wavelength components may be attained by regulating the diameter of the nano Si columns 66 (Φ_{Si}).

According to the investigational results in the present exemplary embodiment, it was confirmed that visible light was obtained at a diameter Φ_{Si} of 4 nm or less, and that red, green, and blue light may be selected by making the diameter smaller. In addition, it was shown that the height (h_{Si}) of the nano Si columns 66 controlled the light emission efficiency and influenced the stability of emission wavelength.

FIG. 23 is a graph showing the relation between the size of the nano Si and the light emission efficiency and emission wavelength obtained by a nano Si light-emitting element. Here, the relation between the height h_{Si} and the light emission efficiency and emission wavelength at a constant diameter Φ_{Si} of 4 nm or less is shown. As shown in FIG. 23, when the height h_{Si} is smaller than twice of the diameter Φ_{Si}, the light emission efficiency decreases and the emission wavelength shifts to the long wavelength (infrared) side, further the variation with respect to the height h_{Si} becomes large, whereby stabilization is not attained.

On the other hand, when the height h_{Si} becomes larger than about 50 times of the diameter Φ_{Si}, the emission wavelength is stabilized at a constant value, but the light emission efficiency decreases. In the case where the height h_{Si} is too small, sufficient quantum confinement effect does not emerge due to a too short distance between the bulk Si (single crystal silicon substrate 60) having a small band gap and the nano Si columns 66. To the contrary, in the case where the height h_{Si} is too large, the resistance of the carriers injected into the nano Si columns 66 increases and the carrier transport efficiency decreases, whereby the aforementioned disadvantages are considered to be developed. Therefore, in order to eliminate useless infrared light and to attain a highly efficient and stable visible light-emitting element, it is desirable that the diameter of the nano Si columns 66 be regulated to be 4 nm or less and that the height thereof be regulated to be in the range of from 2 to 50 times the diameter and preferably from 2 to 25 times.

Next, the relationship between light emission efficiency and crystals on the upper face of the nano Si columns 66 has been investigated in detail. The results of investigation show that the nano Si columns 66 having a uniform crystal face orientation according to the present exemplary embodiment is provided remarkably enhanced light emission efficiency as compared with the related arts where random crystal axes are involved. Further, in relation to the plane direction of the upper face of the nano Si columns (the face directing quasi-perpendicularly to the flow direction of carriers), the light emission efficiency reached a maximum at a crystal structure of (100) followed by (110) and (111). The relation is in the reverse order with the dangling bond density, so that the dangling bonds on the nano Si surface are considered to work as recombination centers for non light-emission. Therefore, it is preferable that the upper face of the nano Si columns 66 be regulated to the plane direction of the (100) face.

FIG. 20 is a fragmentary cross sectional view of a modified example of the nano Si light-emitting element shown in FIG. 17. In order to avoid explanation repetition, the portions that differ from the example shown in FIG. 17 are explained. In the modified example shown in FIG. 20, the thin silicon oxide film 80 is disposed on the upper face of the nano Si columns 66 so as to form the insulating film barrier between the nano Si column 66 and the transparent electrode 69. Namely, in the example shown in FIG. 17, electrons are injected from the transparent electrode 69 to the nano Si column 66 by tunnel-injection through the Schottky barrier (refer to FIG. 19). On the other hand, in the modified example shown in FIG. 20, electrons are injected from the transparent electrode 69 into the nano Si column 66 by tunnel-injection through the insulating barrier (refer to the SiO₂ barrier in FIG. 19). In the modified example, since the upper face of the nano Si columns 66 is covered with the stable and thin silicon oxidized film 80, surface recombination of the electrons injected from the transparent electrode 69 into the nano Si column 66 that is independent of the visible light emission is reduced and the light emission efficiency may be enhanced.

It should be noted that the thickness of the thin silicon oxidized film 80 is generally from about 0.5 nm to about 5 nm, and preferably about 1 nm to about 3 nm.

FIG. 21 is a fragmentary cross sectional view of another modified example of the nano Si light-emitting element shown in FIG. 17. In order to avoid explanation repetition, the portions that differ from the example shown in FIG. 17 are explained.

In the modified example shown in FIG. 21, the nano Si columns 66 have in the height direction thereof a p-n junction with a two-layered structure of a p-type conductive layer and a n-type conductive layer. Either the p-type or n-type layer positioned in the upper layer contacts directly a transparent electrode 69 to form an ohmic contact.

More specifically, in the case where a p-type conductive layer (p-layer) is used in the single crystal silicon substrate 60, a p-n junction 91 is formed by disposing a high concentration n-type conductive layer (n+ layer) 90 in the upper layer of the nano Si columns 66. The p-type and n-type may of course be interchanged.

FIG. 22 is a chart that shows a band structure and carrier flow directions for the purpose of explaining the operation principle of another modified example shown in FIG. 21. In the present exemplary embodiment, electrons flowing from the transparent electrode 69 into the n+ layer 90 are injected into the lower p-layer through the p-n junction 91. Carriers come to recombine at a still deeper position in the nano Si columns 66, so that the surface recombination not contributing to visible light emission in the region where the transparent electrode 69 and the nano Si columns 66 contact each other is reduced, whereby the light emission efficiency is still further enhanced.

Next, a method of producing a nano Si light-emitting element according to the present exemplary embodiment will be explained. FIG. 24 is a fragmentary cross sectional view illustrating a method of producing a nano Si light-emitting element according to the exemplary embodiment 3. The method is illustrated in the order of production steps.

A p-type single crystal silicon substrate 60 having a pair of surfaces configured by the (100) face is prepared first, a silicon nitride film 61 is formed on one surface (on the principal surface) by the CVD (Chemical Vapor Deposition) method, and an aluminum film 62a is formed by the sputtering method (FIG. 24A).

Next, for example, through anodic oxidation in a 1 wt % aqueous sulfuric acid solution, the aluminum film 62a is converted to an aluminum oxide film 62b, and nanometer-size micropores 62 are formed on the surface thereof (FIG. 24B). For example, at an applied voltage of 10 V in the anodic oxidation, the micropores 62 having a hexagonal symmetry with a pitch of about 24 nm and a pore diameter of about 8 nm were self-assembled. The pitch and diameter may be controlled in various sizes by selecting the magnitude of the applied voltage.

Next, after the thin film remaining at the bottom of micropores 62 is removed by wet-etching using phosphoric acid or the RIE (Reactive Ion Etching) process, an inorganic SOG (Spin On Glass) is spin-coated and baked to form an inorganic film 64a composed of an inorganic material. Here, the micropores may be filled adequately and the surface of the inorganic film 64a may be flattened by selecting the viscosity of the SOG as appropriate (FIG. 24C).

Next, the surface of the inorganic film 64a is slightly etched (etch back) by the RIE process so as to obtain an inorganic film 64b that is remaining only in the micropores 62 (FIG. 24D).

Further, for example, through wet etching using an aqueous phosphoric acid solution in a low concentration, the aluminum oxide film 62b is selectively removed to form aperture portion 63 (FIG. 24E).

Subsequently, the upper layer (for example, 15 nm deep) of a silicon nitride film 61 and the single crystal silicon substrate 60 is etched by the conventional RIE process using the inorganic film 64b as a mask so as to form the nano Si columns (cylindrical protrusions) 66 and depressions 65 (FIG. 24F).

Thereafter, for example, after the inorganic film 64b is selectively removed by wet etching using an aqueous hydrofluoric acid solution, through heat treatment in an oxidative atmosphere using the silicon nitride film 61 as a protective mask, a thick silicon oxide film 67 is formed on the bottom of the depressions 65 and the side faces of the nano Si columns 66 (FIG. 24G). At this time, the thick silicon oxide film 67 was controlled to a predetermined thickness so as to regulate the diameter of the nano Si columns 66 at about 2.5 nm.

Finally, after the silicon nitride film 61 is selectively removed by heat phosphoric acid, the transparent electrode (ITO) 69 composed of a compound based on indium oxide is formed on the principal surface side on which the nano Si columns 66 are provided, and the metal electrode 68 of aluminum is formed on the other surface side so as to obtain a nano Si light-emitting element as shown in FIG. 17.

The nano Si column 66 of the nano Si light-emitting element obtained as described above has a diameter of about 2.5 nm and a height of about 50 nm. The emission of green color light having a peak wavelength of about 550 nm is confirmed by applying a voltage across the transparent electrode 69 serving as a cathode and the metal electrode 68 serving as an anode.

The light emission efficiency of the nano Si light-emitting element has been remarkably enhanced due to the following reasons.

Firstly, the nano Si columns 66 have the same crystal face orientation as the single crystal silicon substrate 60 and have a uniform crystal face orientation of (100), so that the number of recombination that does not contribute to light emission at the upper face (Schottky contact face 70) of the nano Si columns 66 into which electrons are injected may be minimized.

In addition, the nano Si columns 66 may have crystallinity almost free of defects because the nano Si columns 66 are cut out of the single crystal silicon substrate 60 that has an extremely excellent crystallinity.

Further, the nano Si columns 66 are processed using as an etching mask the micropores 62 with a uniform diameter obtained by anodic oxidation of aluminum, and the diameter thereof is finely regulated by the oxidation step after the anodic oxidation, so that a nano Si light-emitting element having an excellent uniformity in size may be formed.

As a result, an extremely excellent controllability of emission wavelength may be attained. According to an experiment, the variation in size was suppressed within 20% or less.

Still further, by changing the size of the nanoparticles an element having a different emission wavelength may be easily produced in the similar production process.

According to an experiment, blue color light was emitted when the diameter of the nano Si columns 66 is about 2 nm, green color at about 2.5 nm, and red color at about 3.3 nm. A mixture thereof was confirmed to provide white color.

In addition, the thick silicon oxide film 67 enclosing the nano Si columns 66 works to provide an electrical insulating separation from the transparent electrode 69 and to stabilize the mechanical strength of the nano Si columns 66 as well.

Therefore, according to the present exemplary embodiment, a nano Si light-emitting element having a desired wavelength may be provided with a high yield in a cost-effective manner.

It should be noted that, as the transparent electrode 69, ITO was exemplified, but any material may be used without any particular limitation as long as the material keeps transparency to visible light and possesses electrical conductivity. Further, as the metal electrode 68, aluminum was exemplified, but any material may be used without any particular limitation as long as the material is excellent in electrical conductivity and makes an ohmic contact with the silicon substrate.

The completed form of the light-emitting element of the production method shown in FIG. 24 was exemplified by the same nano Si light-emitting element as the one shown in FIG. 17, but may be modified in various manners. For example, in FIG. 24H, after the silicon nitride film 61 is selectively removed by hot phosphoric acid, a thin silicon oxide film 80 (refer to FIG. 20) may be formed on the upper face of the nano Si columns 66 by thermal oxidation. This process may lead to an embodiment where the transparent electrode 69 and the nano Si columns 66 contact each other through a thin oxide film, that is, the exemplary embodiment of a modified example shown in FIG. 20.

Further, for example, in FIG. 24H, after the silicon nitride film 61 is selectively removed with hot phosphoric acid, a high concentration n+ layer (n-type conductive layer) (refer to FIG. 21) may be formed on the upper face of the nano Si columns 66 by ion injection or plasma doping or the like. This process may lead to an embodiment where the transparent electrode 69 and the nano Si columns 66 contact each other through a p-n junction, that is, the exemplary embodiment of a modified example shown in FIG. 21.

In the foregoing exemplary embodiment, a p-type conductive layer is used as the single crystal silicon substrate 60, but an n-type conductive layer may be used. In this case, the n+ layer 90 is replaced by a p+ layer and the relation between the cathode and anode is also reversed.

FIG. 25 is fragmentary cross sectional views illustrating another method of producing a nano Si light-emitting element according to the exemplary embodiment 3. The method is illustrated in the order of production steps.

As shown in FIG. 25, a p-type single crystal silicon substrate 60 having a pair of surfaces composed of the (100) face is prepared first, and a silicon nitride film 61 is formed on one surface (principal surface) by the CVD method. Further, after a polymer thin film 71 made of a block copolymer (for example, a copolymer of polystyrene (PS) and polymethylmethacrylate (PMMA)) is spin-coated in a thickness of about 25 nm, the polymer thin film 71 is baked at 200° C. for 5 hours to develop a phase separation structure containing a spherical PMMA layer 71b in a thin film of a PS layer 71a.

For example, when a copolymer of PS and PMMA, each having about 40,000 and about 10,000 molecular weight, respectively, was used, a phase separation structure with a hexagonal symmetry having a pitch of about 28 nm and a diameter of about 12 nm for the spherical PMMA layer 71b was obtained. The pitch and sphere diameter may be regulated in various sizes by controlling the molecular weight and the component composition of the block copolymer (FIG. 25A).

Then, through the RIE process using oxygen gas, which takes advantage of the etching rate difference between PS and PMMA, nanometer-size micropores 72 having a hexagonal symmetry plane pattern are formed on the surface of the polymer thin film 71. The formation is achieved because the PMMA layer 71b has an etching rate 3 to 5 times larger than the PS layer 71a in oxygen gas plasma (FIG. 25B).

Next, an inorganic SOG (Spin On Glass) is spin-coated and baked to form an inorganic film 64a composed of an inorganic material. Here, the micropores may be filled adequately and the surface of the inorganic film 64a may be flattened by selecting the viscosity of the SOG as appropriate (FIG. 25C).

Next, the surface of the inorganic film 64a is slightly etched (etch back) by the RIE process so as to obtain an inorganic film 64b that is remaining only in the micropores 72 (FIG. 25B) (FIG. 25D).

Subsequently, etching is conducted by using the RIE process, and the PS layer 71a in the area that is not covered with the inorganic film 64b is removed so as to form the aperture portion 73 (FIG. 25E).

Next, the upper layer (for example, 40 nm deep) of a silicon nitride film 61 and the single crystal silicon substrate 60 is etched by the RIE process using the inorganic film 64b as a mask so as to form the nano Si columns (cylindrical protrusions) 66 and depressions 65 (FIG. 25F).

Thereafter, for example, after the inorganic film 64b is removed by wet processing using an aqueous hydrofluoric acid solution, through heat treatment in an oxidative atmosphere using the silicon nitride film 61 as a protective mask, a thick silicon oxide film 67 is formed on the bottom of the depressions 65 and the side faces of the nano Si columns 66 (FIG. 25G). At this time, the thick silicon oxide film 67 is controlled to a predetermined thickness so as to regulate the diameter of the nano Si columns 66 at about 2 nm.

Finally, after the silicon nitride film 61 is selectively removed by heat phosphoric acid, the transparent electrode (ITO) 69 composed of a compound based on indium oxide is formed on the principal surface side on which the nano Si columns 66 are provided, and the metal electrode 68 of aluminum is formed on the other surface side (FIG. 25H) so as to obtain a nano Si light-emitting element as shown in FIG. 17.

The nano Si column 66 of the nano Si light-emitting element obtained as described above has a diameter of about 2 nm and a height of about 40 nm. The emission of blue color light having a peak wavelength of about 430 nm is confirmed by applying a voltage across the transparent electrode 69 serving as a cathode and the metal electrode 68 serving as an anode.

The light emission efficiency of the nano Si light-emitting element has been remarkably enhanced due to the following reasons.

Firstly, the nano Si columns 66 of the nano Si light-emitting element have the same crystal face orientation as the single crystal silicon substrate 60 and have a uniform crystal face orientation of (100), so that the number of recombination that does not contribute to light emission at the upper face (Schottky contact face 70) of the nano Si columns 66 into which electrons are injected may be minimized.

In addition, the nano Si columns 66 may have crystallinity almost free of defects because the nano Si columns 66 are cut out of the single crystal silicon substrate 60 that has an extremely excellent crystallinity.

Further, the nano Si columns 66 are processed using as an etching mask the micropores 72 with a uniform diameter obtained by a phase-separated structure of the block copolymer, and the diameter thereof is finely regulated by the oxidation step thereafter, so that a nano Si light-emitting element having an excellent uniformity in size may be formed. As a result, an extremely excellent controllability of emission wavelength may be attained. According to an experiment, the variation in size was suppressed within 15% or less.

Still further, by changing the size of the inorganic film 64b, an element having a different emission wavelength may be easily produced in the similar production process. According to an experiment, blue color light was emitted when the diameter of the nano Si column 66 is about 2 nm, green color was emitted when the diameter of the nano Si column 66 is 2.5 nm, and red color was emitted when the diameter of the nano Si column 66 is about 3.3 nm. A mixture thereof was confirmed to provide white color.

In addition, the thick silicon oxide film 67 enclosing the nano Si columns 66 works to provide an electrical insulating separation from the transparent electrode 69 and to stabilize the mechanical strength of the nano Si columns 66 as well. Therefore, according to the present exemplary embodiment, a nano Si light-emitting element having a desired wavelength may be provided with a high yield in a cost-effective manner.

It should be noted that, as the transparent electrode 69, ITO was exemplified, but any material maybe used without any particular limitation as long as the material keeps transparency to visible light and possesses electrical conductivity. Further, as the metal electrode 68, aluminum was exemplified, but any material may be used without any particular limitation as long as the material is excellent in electrical conductivity and makes an ohmic contact with the silicon substrate.

The completed form of the light-emitting element of the production method shown in FIG. 25 is exemplified by the same nano Si light-emitting element as the one shown in FIG. 17, but may be modified in various manners. For example, in FIG. 25H, after the silicon nitride film 61 is selectively removed by hot phosphoric acid, a thin silicon oxide film 80 (refer to FIG. 20) may be formed on the upper face of the nano Si columns 66 by thermal oxidation. This process may lead to an embodiment where the transparent electrode 69 and the nano Si columns 66 contact each other through a thin silicon oxide film 80, that is, the exemplary embodiment of a modified example shown in FIG. 20.

Further, for example, in FIG. 24H, after the silicon nitride film 61 is selectively removed with hot phosphoric acid, a high concentration n+ layer (n-type conductive layer) (refer to FIG. 21) may be formed on the upper face of the nano Si columns 66 by ion injection or plasma doping or the like. This process may lead to an embodiment where the transparent electrode 69 and the nano Si columns 66 contact each other through a p-n junction 91, that is, the exemplary embodiment of a modified example shown in FIG. 21.

Further, in FIG. 25G, after the thick silicon oxide film 67 is formed, an inorganic insulating layer 74 is embedded in the depressions 65 (FIG. 25F) by SOG coating and etch back, so that a structure shown in FIG. 26 may also be attained. FIG. 26 is a fragmentary cross sectional view of another modified example of the nano Si light-emitting element shown in FIG. 17. The inorganic insulating layer 74 embedded in the depressions 65 may reinforce the mechanical strength of the nano Si columns 66 and strengthen the insulating separation between the transparent electrode 69 and the single crystal silicon substrate 60. In addition, the structure is almost flat, so that the transparent electrode 69 may be formed easily, whereby an effect of improving the production yield of the element may also be attained. Further, use of the SOG embedding step may eliminate the step of forming the aforementioned silicon nitride film 61.

There is no limitation on the inorganic SOG for forming the inorganic film 64b as long as the inorganic SOG serves as a mask for silicon etching, and a titanium (Ti) based metalloxane polymer is desirable. As the resulting inorganic film 64b, titanium oxide (TiO₂) is desirable.

Further, there is no limitation on the Si dry-etching for forming the nano Si columns 66 as long as Si columns having a desired aspect ratio are formed, and low temperature (below minus 100° C.) etching process using sulfur hexafluoride (SF₆) gas is suitable considering the conformity with the aforementioned material used as the etching mask.

In the foregoing exemplary embodiment, a p-type conductive layer is used as the single crystal silicon substrate 60, but an n-type conductive layer may be used. In this case, the n+ layer 90 is replaced by a p+ layer and the relation between the cathode and anode is also reversed.

In this way, as mentioned above in detail, according to the exemplary embodiment 3, crystal silicons such as the nano Si have a uniform crystal face orientation and the nano Si is directly cut out of the silicon substrate of single crystal by using the nano particles so that a nano Si light-emitting element having a high quality crystal (high efficiency) with reduced number of non light-emission recombination centers and an excellent controllability in particle diameter (controllability in emission wavelength) may be attained. As a result, there may be provided in a cost-effective manner, a long-life, highly efficient nano Si light-emitting element emitting any light freely from three principal colors to white color.

Note that, in the exemplary embodiments 1, 2, and 3, light-emitting elements having the nano Si are exemplified, but the same configurations may also be applied to power generating elements (photovoltaic elements). Namely, by irradiating light to the nano Si from the transparent electrode side, carriers (electron and hole pairs) are generated, and electric power maybe outputted from the pair of the electrodes. In particular, a power generating element highly sensitive to visible to ultraviolet light may be attained.

In addition, a nano Si element in accordance with the exemplary embodiments 1, 2, and 3 maybe produced easily in an arbitrary shape by adding several production steps to conventional IC production processes. The nano Si element maybe hybridized into a single chip together with a control circuit, an amplifier circuit, a memory circuit, a protection circuit, and others. Namely, the nano Si element and various circuits are mounted on the same board into an IC chip, so that various functions and improvements may be combined or cost reduction may be expected. The applications thereof are not limited to the light-emitting elements and power generating elements, but maybe extended to laser applications, radar, communication applications, memories, sensors, electron emitters, displays, or the like.

### BRIEF DESCRIPTION OF THE DRAWINGS

FIG. 1 is a fragmentary cross sectional view of a nano Si light-emitting element in accordance with an exemplary embodiment of the first crystal silicon element.

FIG. 2 is a perspective view of the nano Si light-emitting element shown in FIG. 1.

FIG. 3 is a chart that shows a band structure and carrier flow directions for explaining the operation principle shown in FIGS. 1 and 2.

FIG. 4 is a fragmentary cross sectional view of a modified example of the nano Si light-emitting element shown in FIG. 1.

FIG. 5 is a fragmentary cross sectional view of another modified example of the nano Si light-emitting element shown in FIG. 1.

FIG. 6 is a chart that shows a band structure and carrier flow directions for the purpose of explaining the operation principle of the modified example shown in FIG. 5.

FIG. 7 is a graph showing the relationship between the size of the nano Si and the peak value of emission wavelength obtained for a nano Si light-emitting element.

FIG. 8 shows still another modified example in the exemplary embodiment 1, showing a fragmentary cross sectional view of a white color nano Si light-emitting element.

FIG. 9-1 and FIG. 9-2 are fragmentary cross sectional views illustrating a method of producing a nano Si light-emitting element according to the exemplary embodiment 1.

FIG. 10-1 and FIG. 10-2 are fragmentary cross sectional views illustrating another method of producing a nano Si light-emitting element according to the exemplary embodiment 1.

FIG. 11 is a fragmentary cross sectional view of a nano Si light-emitting element in accordance with an exemplary embodiment of the aforementioned second crystal silicon element.

FIG. 12 is a chart that shows a band structure and carrier flow directions for explaining the operation principle shown in FIG. 11.

FIG. 13 is a fragmentary cross sectional view of a modified example of the nano Si light-emitting element shown in FIG. 11.

FIG. 14 is a chart that shows a band structure and carrier flow directions for the purpose of explaining the operation principle of the modified example shown in FIG. 13.

FIG. 15-1 and FIG. 15-2 are fragmentary cross sectional views illustrating a method of producing a nano Si light-emitting element according to the exemplary embodiment 2.

FIG. 16-1 and FIG. 16-2 are fragmentary cross sectional views illustrating another method of producing a nano Si light-emitting element in the order of production steps according to the exemplary embodiment 2.

FIG. 17 is a fragmentary cross sectional view that illustrates a nano Si light-emitting element in accordance with an exemplary embodiment of the third crystal silicon element.

FIG. 18 is a perspective view that illustrates the nano Si light-emitting element shown in FIG. 17.

FIG. 19 is a chart that shows a band structure and carrier flow directions for explaining the operation principle shown in FIGS. 17 and 18.

FIG. 20 is a fragmentary cross sectional view of a modified example of the nano Si light-emitting element shown in FIG. 17.

FIG. 21 is a fragmentary cross sectional view of another modified example of the nano Si light-emitting element shown in FIG. 17.

FIG. 22 is a chart that shows a band structure and carrier flow directions for the purpose of explaining the operation principle of another modified example shown in FIG. 21.

FIG. 23 is a graph showing the relation between the size of the nano Si and the light emission efficiency and emission wavelength obtained by a nano Si light-emitting element.

FIG. 24 is a fragmentary cross sectional view illustrating a method of producing a nano Si light-emitting element according to the exemplary embodiment 3.

FIG. 25 is fragmentary cross sectional views illustrating another method of producing a nano Si light-emitting element according to the exemplary embodiment 3.

FIG. 26 is a fragmentary cross sectional view of another modified example of the nano Si light-emitting element shown in FIG. 17.

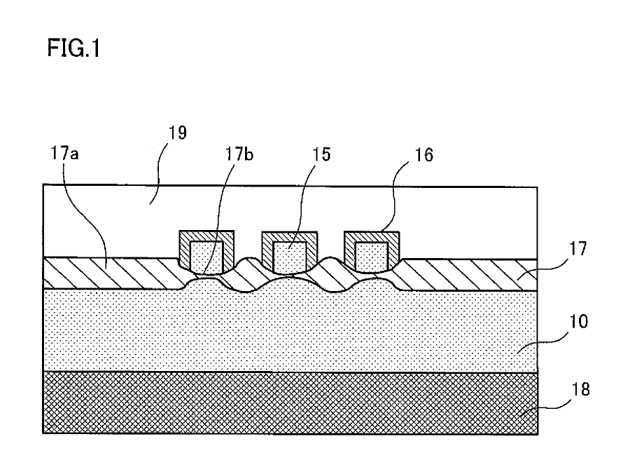

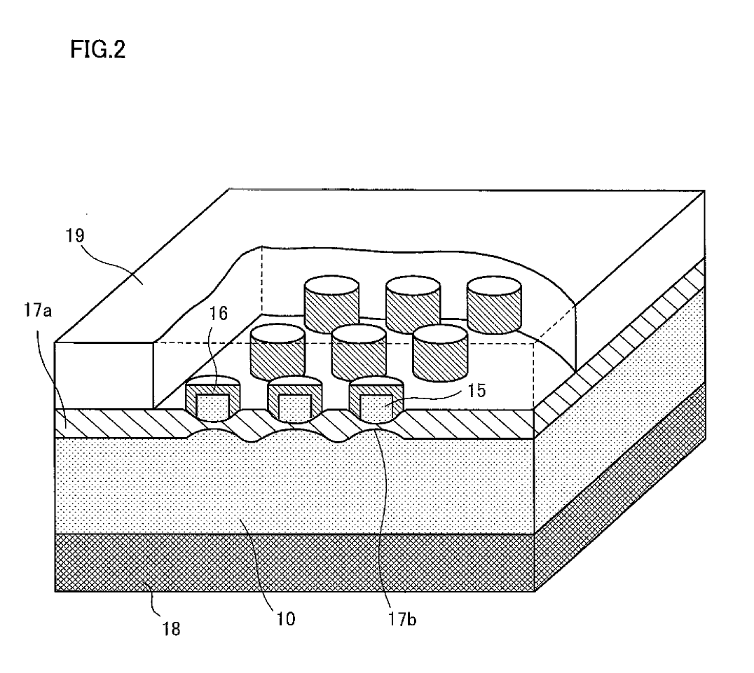

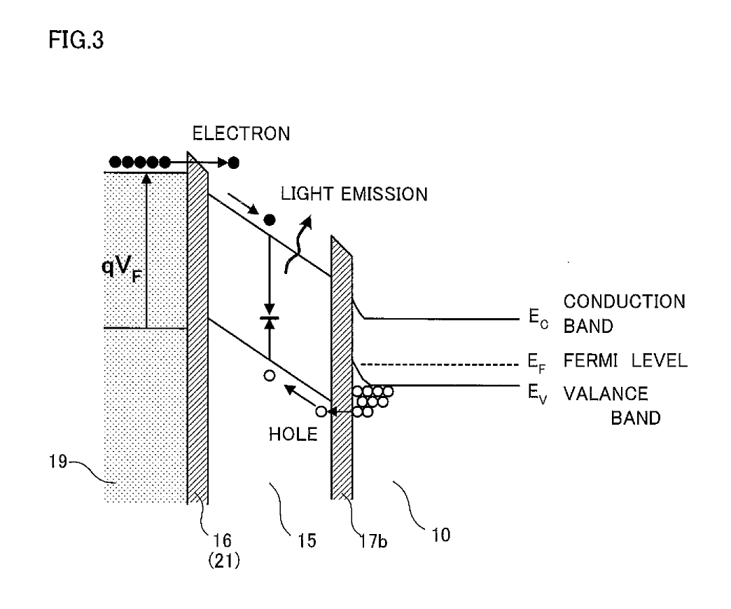

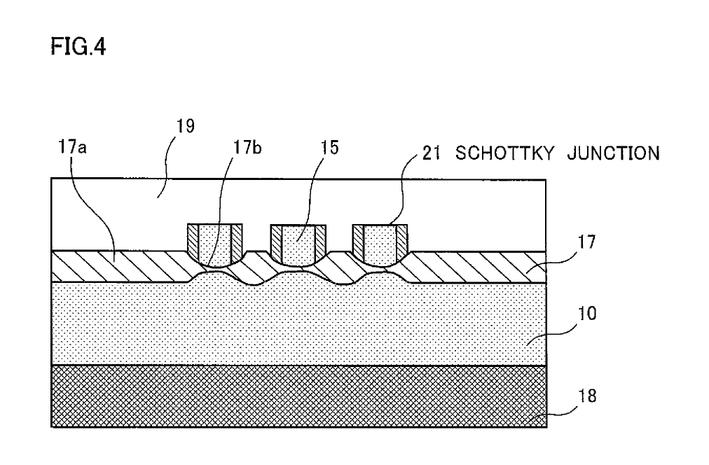

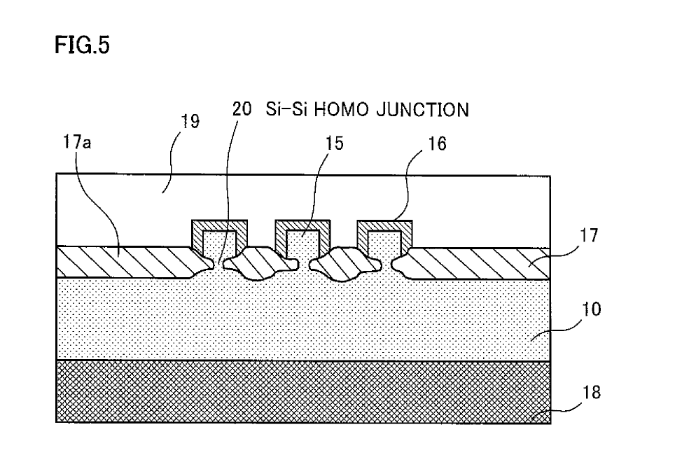

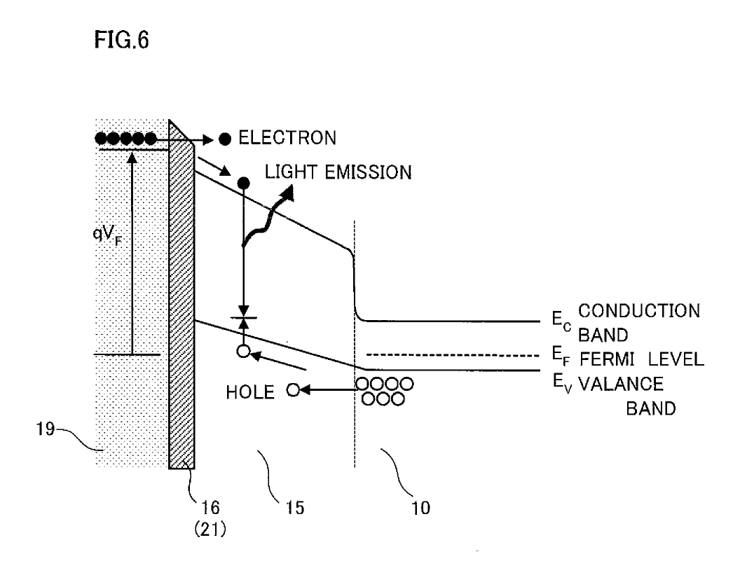

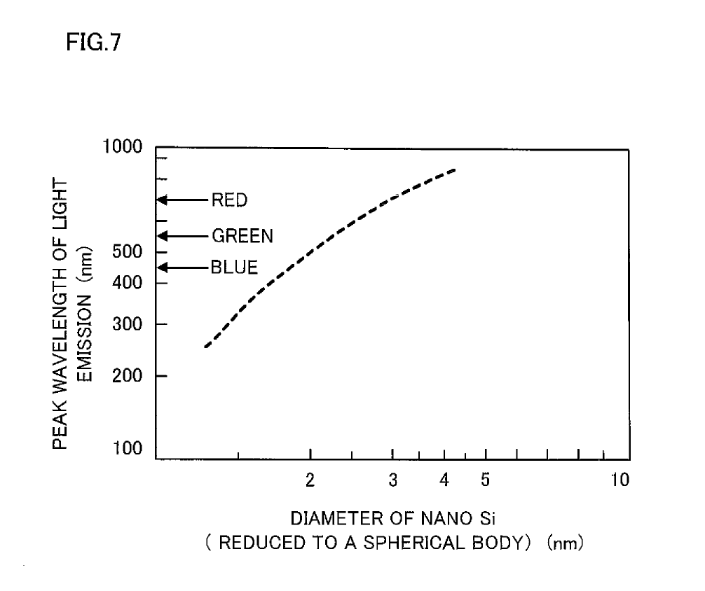

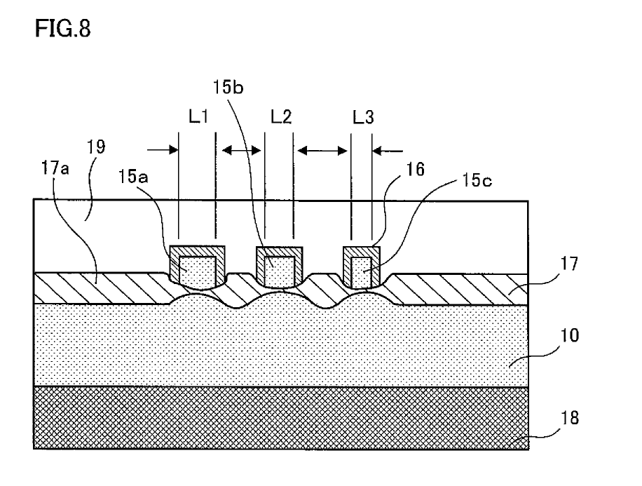

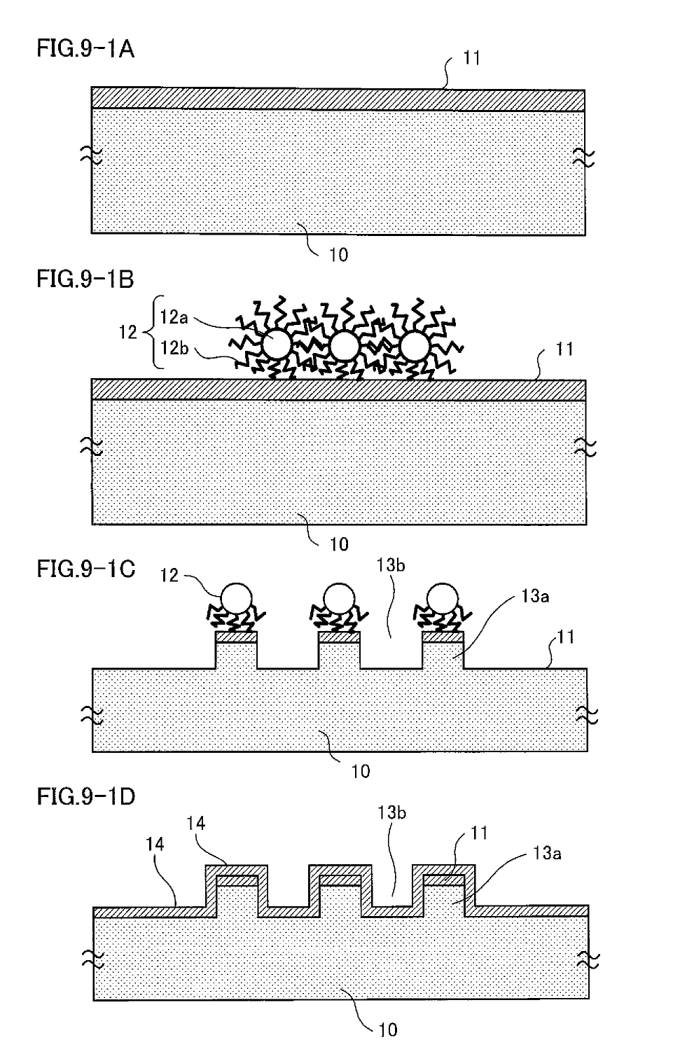

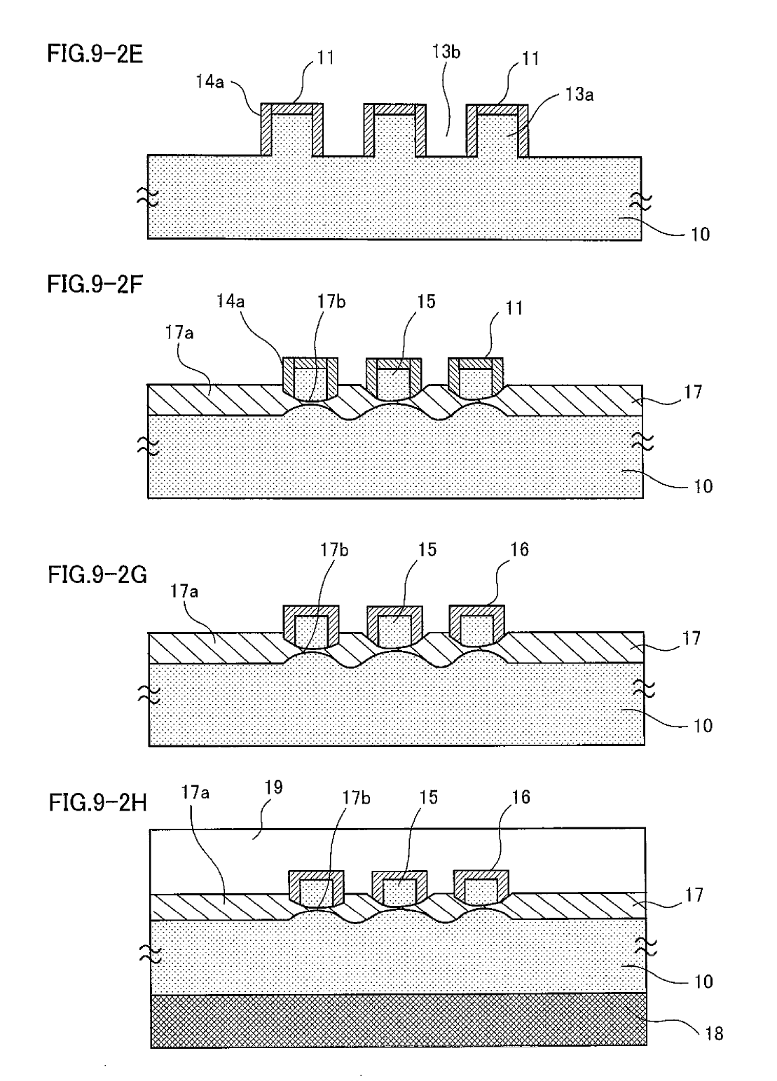

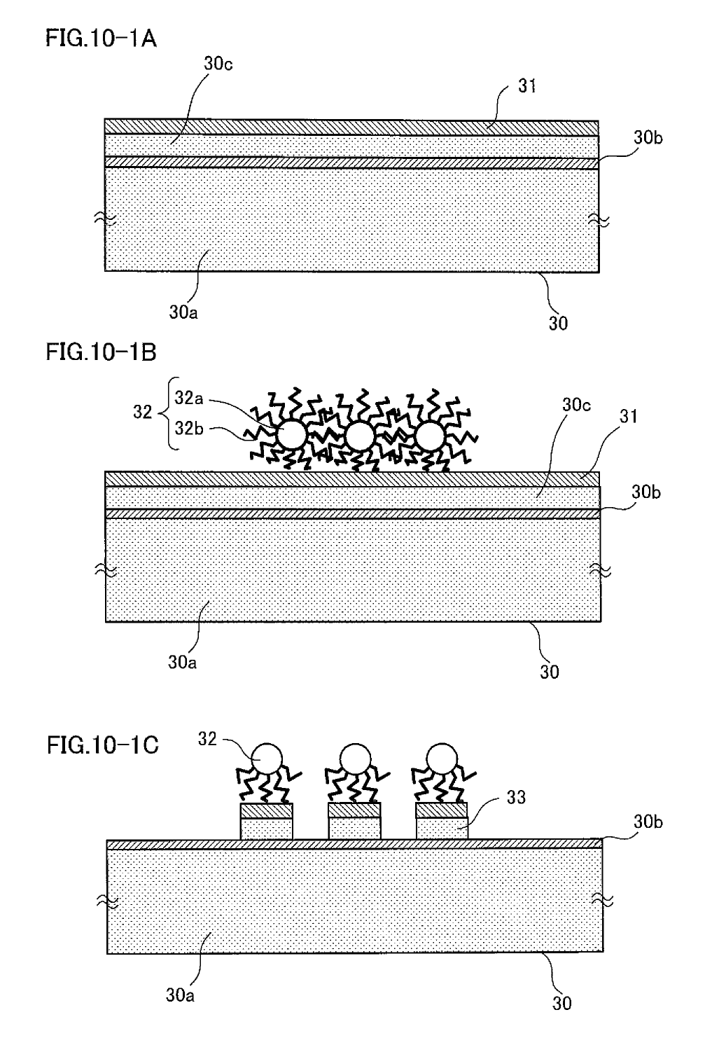

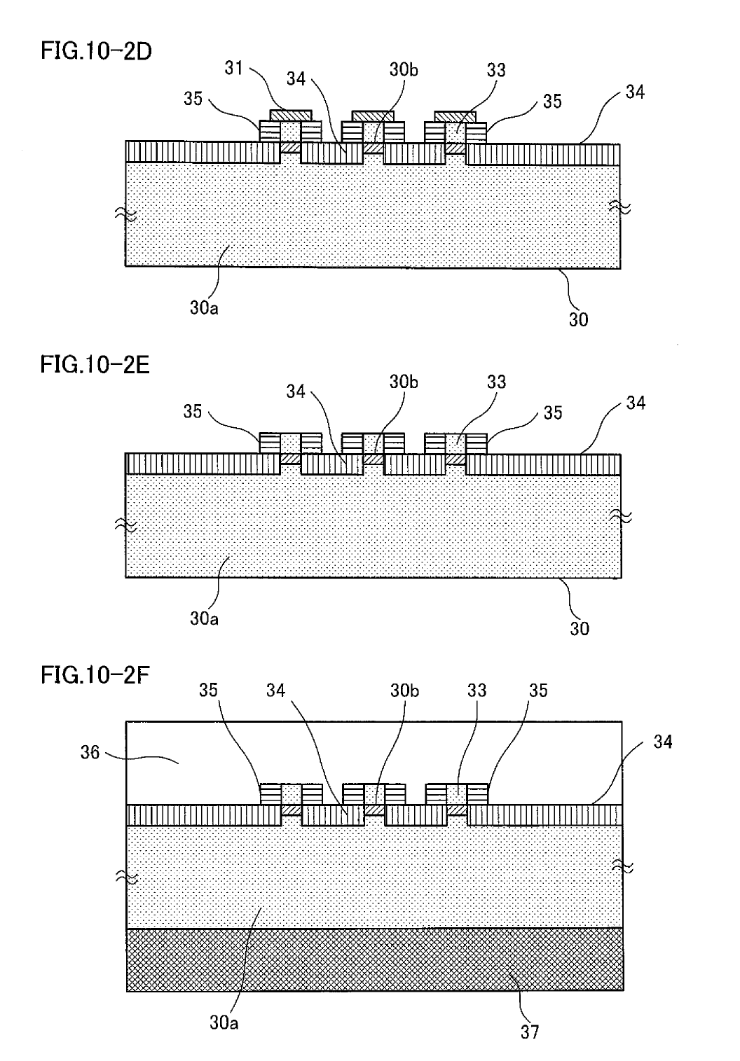

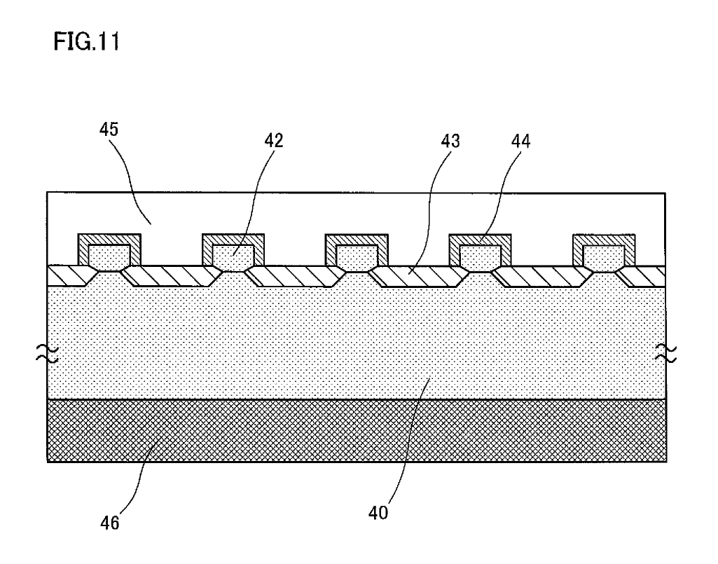

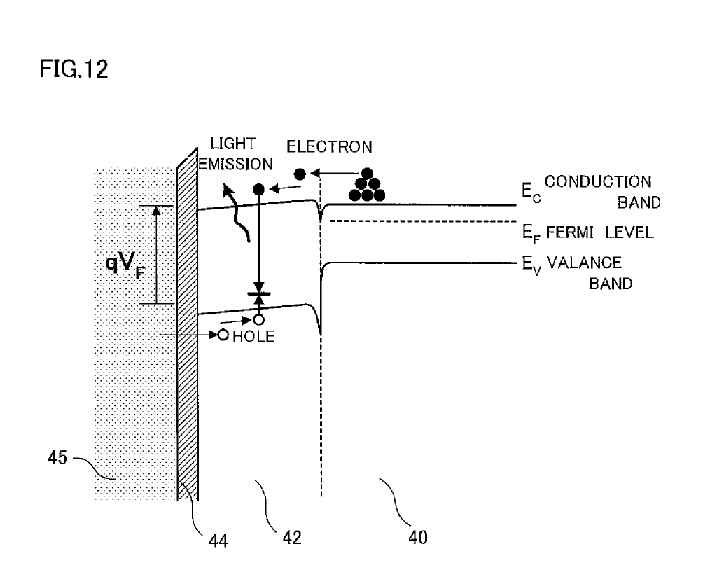

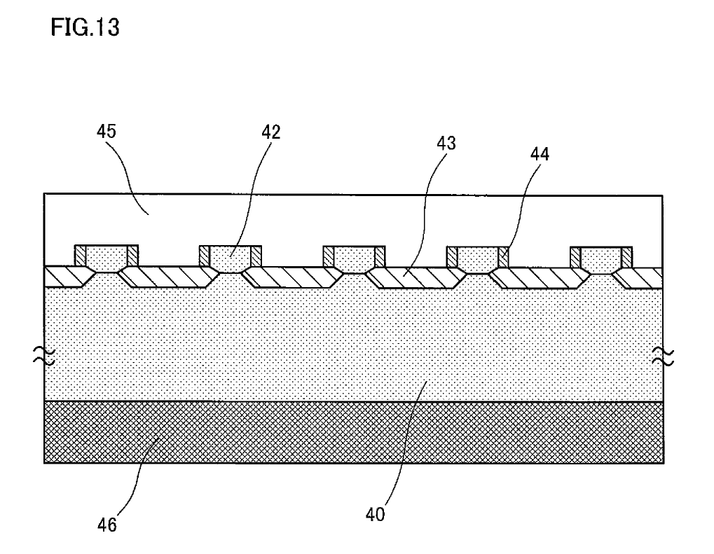

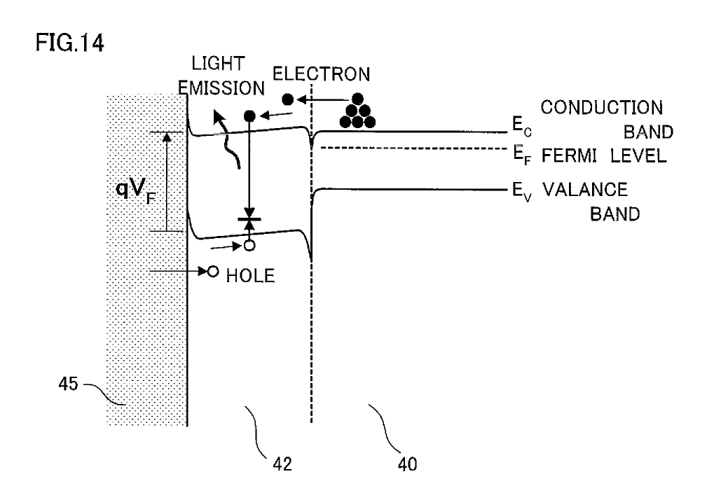

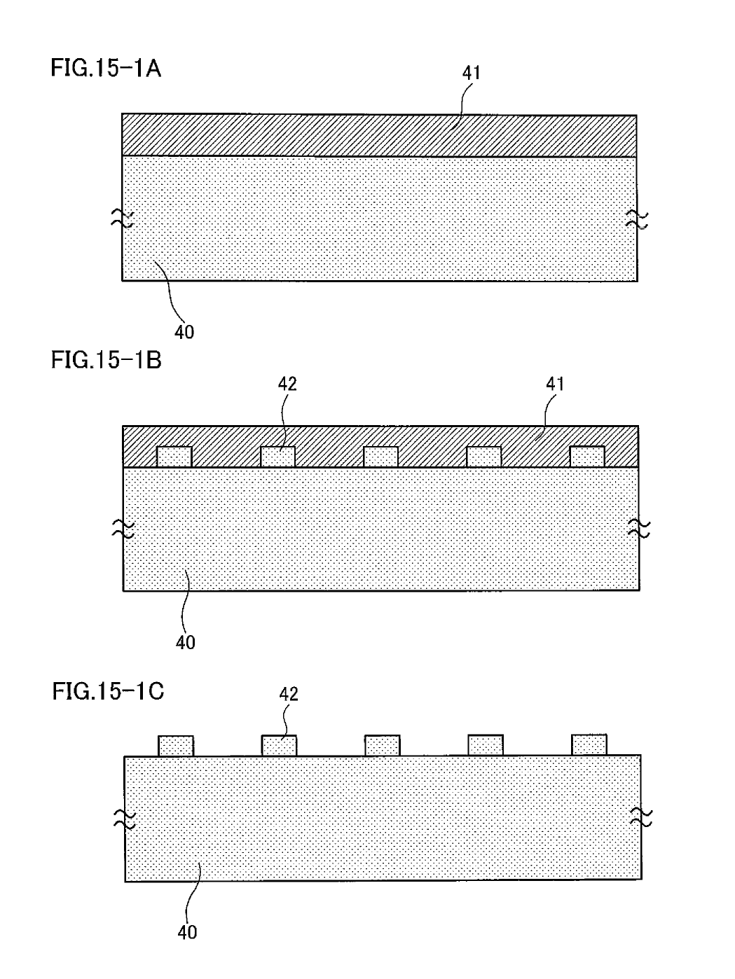

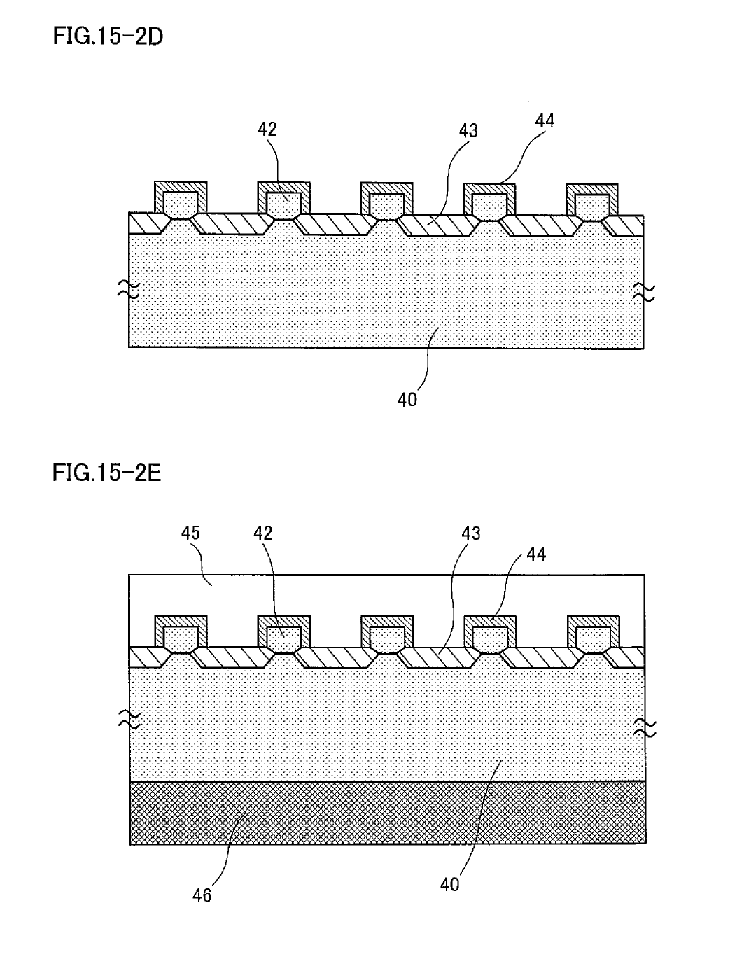

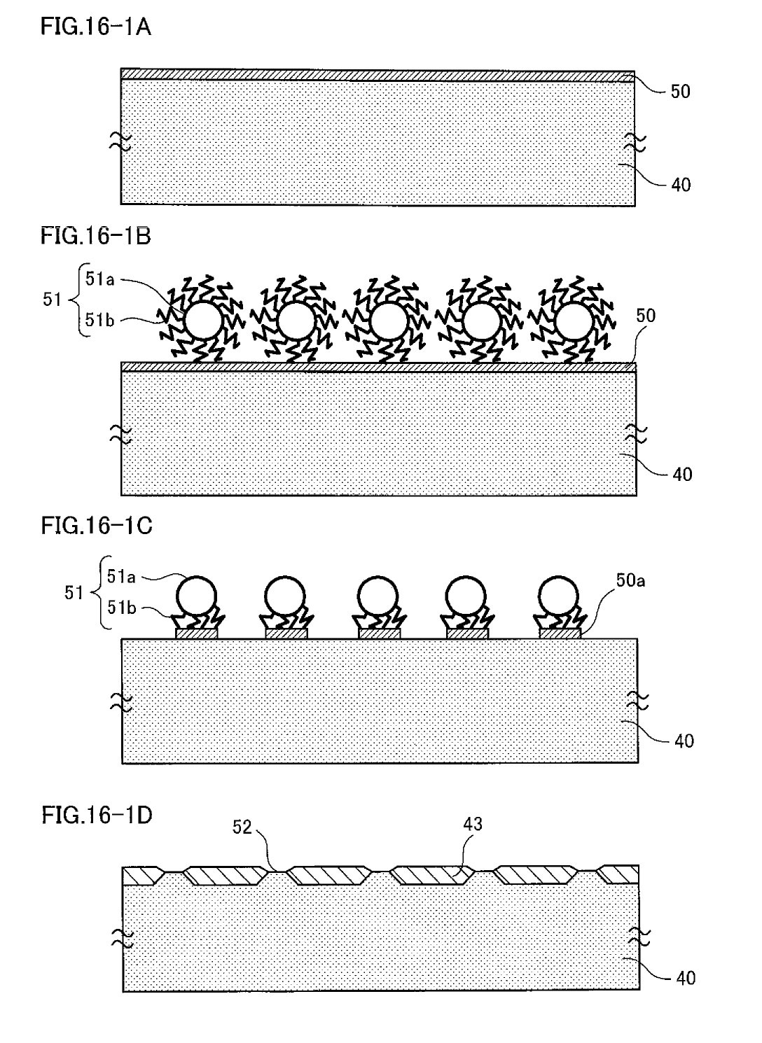

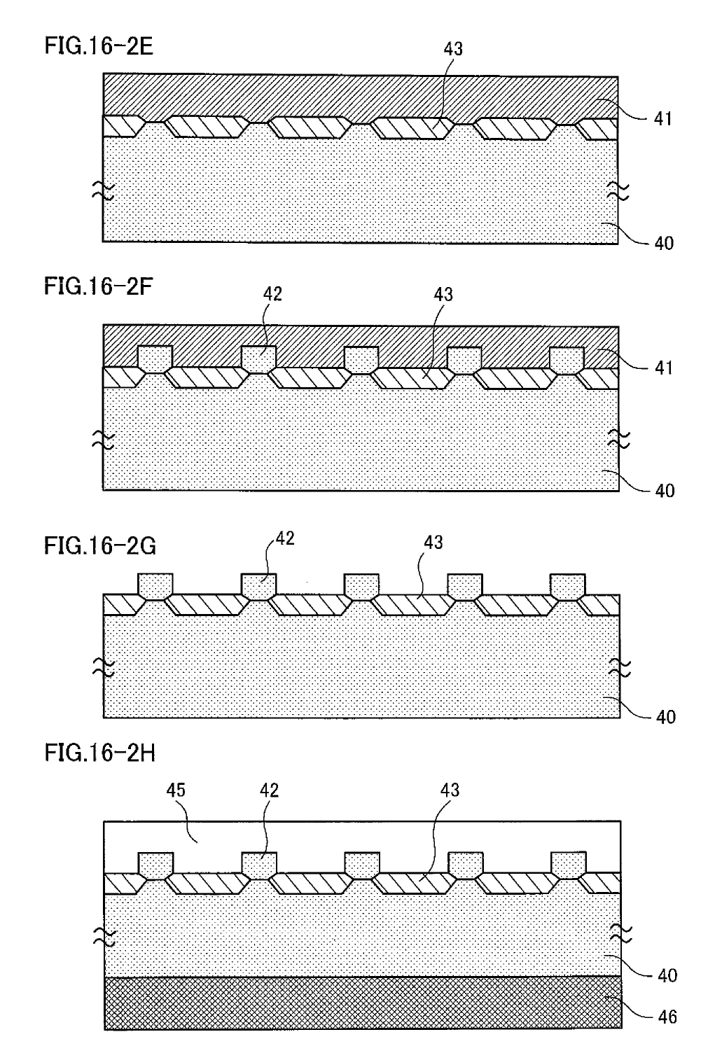

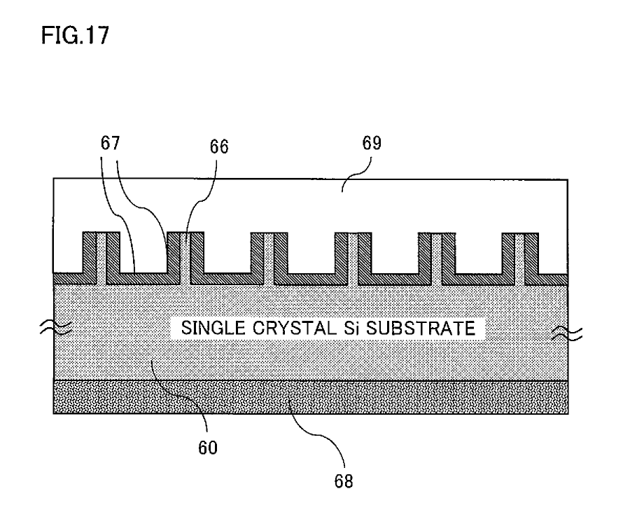

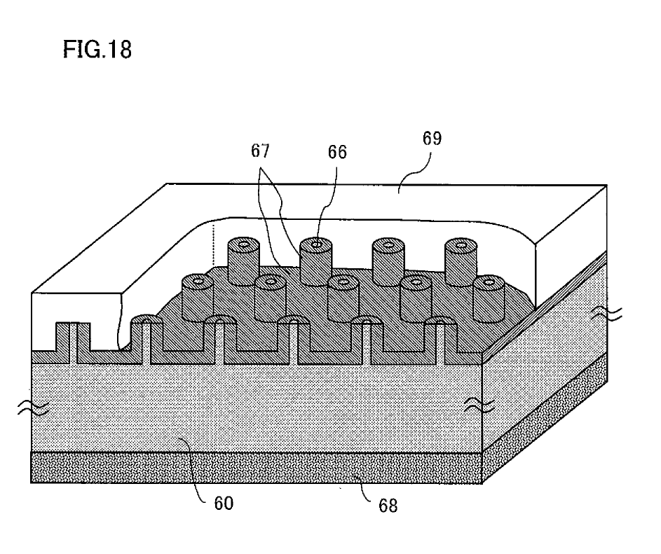

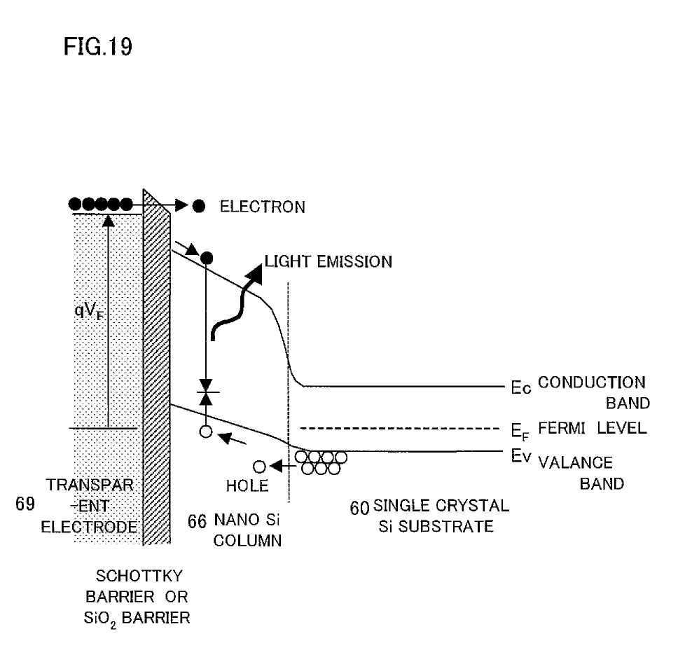

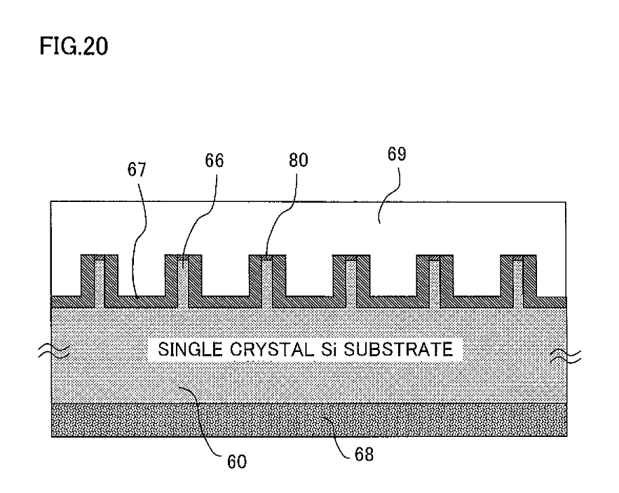

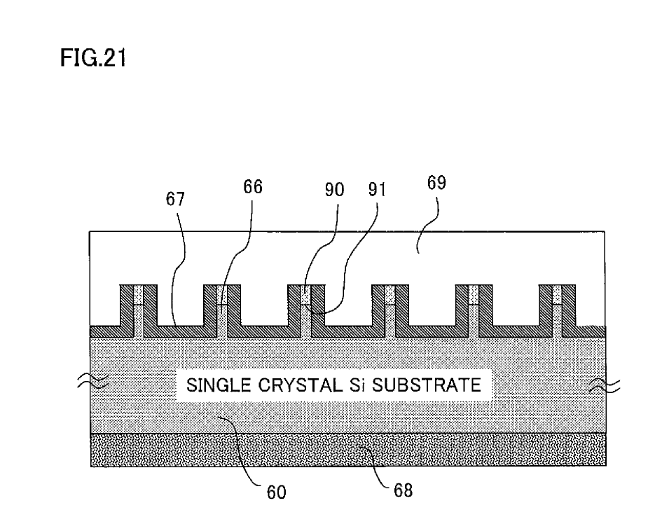

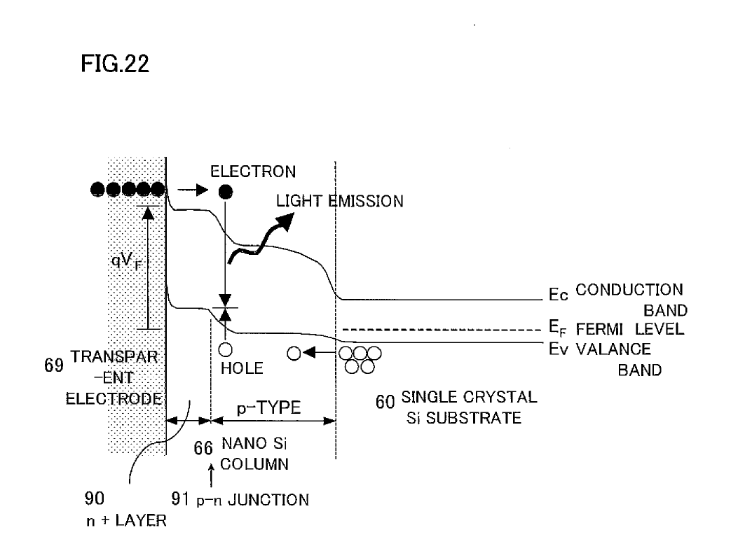

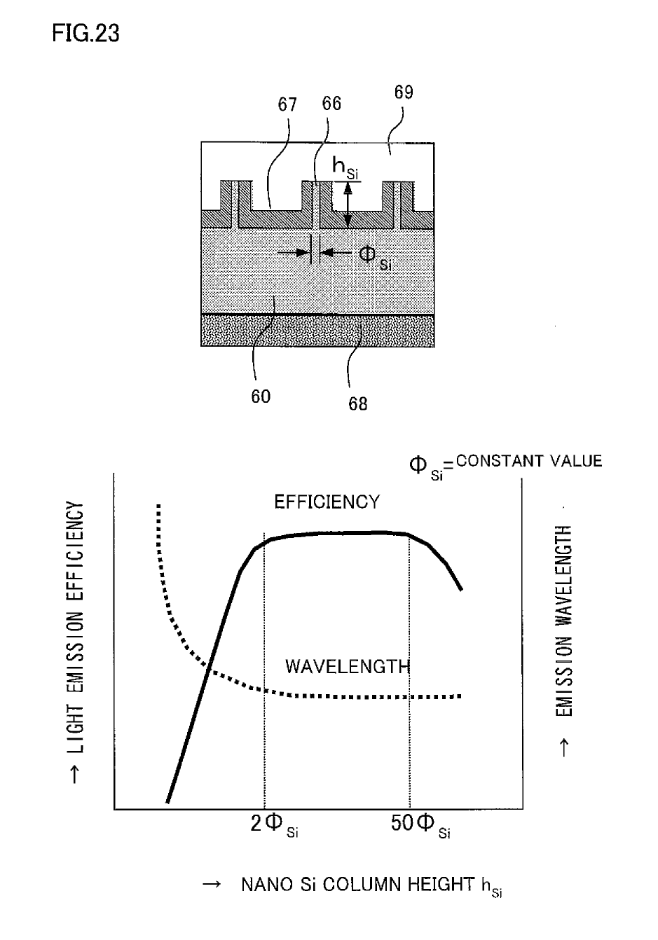

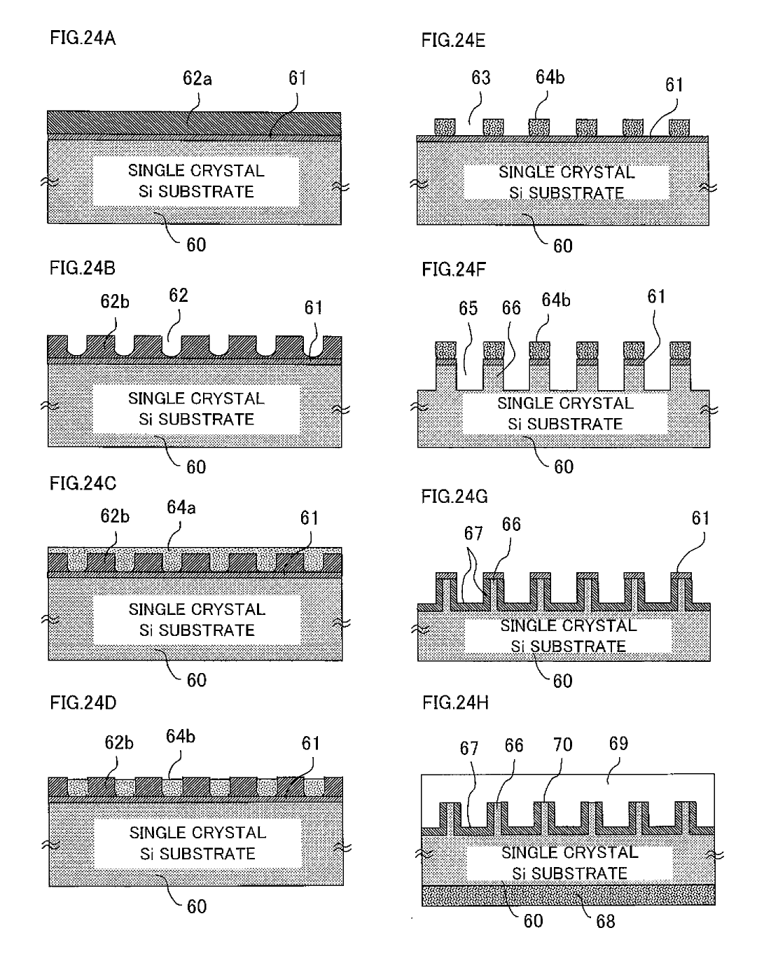

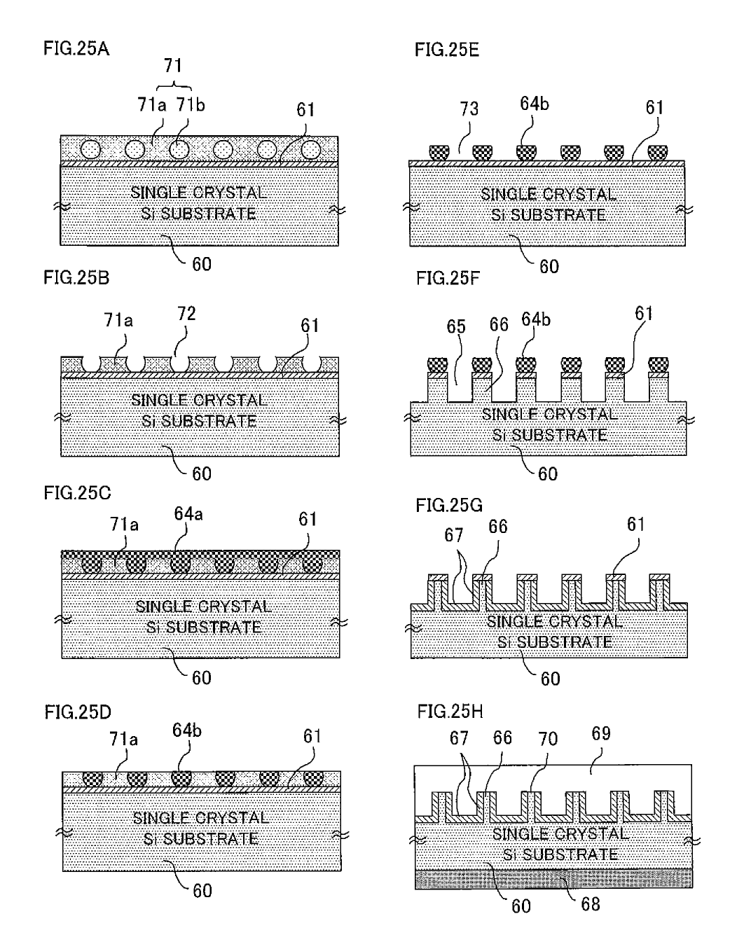

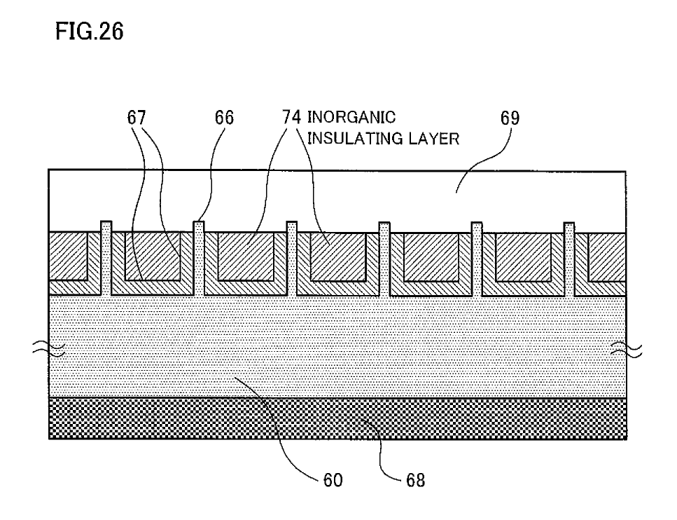

### DESCRIPTION OF THE NUMERALS

10 . . . silicon substrate, 11, 14, 31 . . . silicon nitride film, 12, 32 . . . nano particle, 15,33 . . . nano Si, 16 . . . thin silicon oxide film, 17, 34, 35 . . . silicon oxide film, 18, 37 . . . metal electrode, 19, 36 . . . transparent electrode, 20 . . . Si-Si homo-contact, 21 . . . schottky junction, 30 . . . SOI substrate, 40 . . . silicon substrate, 41 . . . Al and Si alloy film, 42 . . . nano Si (p-type crystal silicon), 43 . . . silicon oxide film, 44 . . . silicon oxide film, 45 . . . transparent electrode (for example, ITO), 46 . . . metal electrode (for example, aluminum), 50 . . . silicon nitride film, 51 . . . nano particle, 60 . . . single crystal silicon substrate, 61 . . . silicon nitride film, 62a . . . aluminum film, 62, 72 . . . micropore, 63, 73 . . . aperture portion, 64a, 64b . . . inorganic film, 65 . . . depression, 66 . . . nano Si column, 67 . . . thick silicon oxide film, 68 . . . metal electrode, 69 . . . transparent film, 70 . . . schottky contact face, 74 . . . inorganic insulating layer, 80 . . . thin silicon oxide film, 90 . . . n+ layer (n-type conductive layer), 91 . . . p-n junction

1. A crystal silicon element comprising:
a silicon substrate; and
a nanometer-size crystal silicon that is disposed on one surface of the silicon substrate and has the same crystal face orientation as the silicon substrate.

2. The crystal silicon element according to claim 1, further comprising:
a metal electrode; and
a transparent electrode that forms a pair of electrodes together with the metal electrode, wherein
the pair of electrodes sandwiches the crystal silicon.

3. The crystal silicon element according to claim 2, wherein
the metal electrode is disposed on the other surface opposite to the one surface of the silicon substrate and has an ohmic contact with the silicon substrate, and
the transparent electrode is disposed on the crystal silicon.

4. The crystal silicon element according to claim 3, wherein the transparent electrode contacts the crystal silicon through an insulating film that carriers are tunnel-injected thereinto.

5. The crystal silicon element according to claim 3, wherein the transparent electrode directly contacts the crystal silicon so as to form a Schottky junction.

6. The crystal silicon element according to claim 1, wherein the crystal silicon has a crystal structure with a crystal face quasi-perpendicularly intersecting the flow line of carriers injected, the crystal face having at least any one of the orientations (100), (110), and (111).

7. The crystal silicon element according to claim 1, wherein
the crystal silicon is disposed separately from the silicon substrate, and
the silicon substrate and the crystal silicon contact each other through an insulating film that are easily tunnel-injected by carriers.

8. The crystal silicon element according to claim 1, wherein the silicon substrate and the crystal silicon contact each other at a contact face having a size smaller than the size of the crystal silicon so as to form a homo-junction.

9. A crystal silicon element comprising:
a silicon substrate that has one surface and the other surface opposite to the one surface;
a nanometer-size crystal silicon that is disposed on the one surface of the silicon substrate and has the same crystal face orientation as the silicon substrate;
a transparent electrode that is formed on the one surface of the silicon substrate, the silicon substrate having the crystal silicon disposed on the one surface; and
a metal electrode that is formed on the other surface of the silicon substrate.

10. The crystal silicon element according to claim 9, wherein the crystal silicon has a quasi-columnar shape whose diameter is 4 nm or less reduced to a spherical body.

11. The crystal silicon element according to claim 9, wherein the crystal silicon has a variation in the diameter of 20% or less and emits any one of red, green and blue monochromatic light.

12. The crystal silicon element according to claim 9, wherein the crystal silicon is shaped in mixed sizes so as to emit red, green and blue light.

13. A method for fabricating a crystal silicon element using silicon microcrystals, the method comprising:
a separating-and-disposing process that separates a plurality of crystal silicons from a silicon substrate and disposes the plurality of crystal silicons on one surface of the silicon substrate, the plurality of crystal silicons being nanometer-sized and having the same crystal face orientation as the silicon substrate;
a transparent electrode disposing process that disposes a transparent electrode on the one surface of the silicon substrate; and
a metal electrode disposing process that disposes a metal electrode on the other surface opposite to the one surface of the silicon substrate.

14. The method according to claim 13, wherein the separating-and-disposing process comprises:
a coating process that coats nano particles dispersed on the one surface of the silicon substrate of a single crystal;
a etching process that etches the one surface of the silicon substrate using the nano particles as a mask so as to form columnar protrusions; and
an oxidizing process that oxidizes the one surface of the silicon substrate except the columnar protrusions so as to isolate the columnar protrusions from the silicon substrate.

15. A method for fabricating a crystal silicon element using silicon microcrystals, the method comprising:
a disposing process that dispersedly disposes nano particles on one surface of a silicon substrate of a single crystal;
an etching process that etches the one surface of the silicon substrate using the nano particles as a mask; and
a removing process that removes the nano particles from the one surface of the silicon substrate.

16. The method according to claim 15, further comprising:
an oxidizing process that oxidizes the one surface of the silicon substrate except columnar protrusions obtained by the etching process so as to isolate the columnar protrusions from the silicon substrate.

17. The method according to claim 15, further comprising:
a transparent electrode disposing process that disposes a transparent electrode on the one surface of the silicon substrate; and
a metal electrode disposing process that disposes a metal electrode on the other surface opposite to the one surface of the silicon substrate.

18. A crystal silicon element comprising:
a n-type single crystal silicon substrate that has one surface and the other surface opposite to the one surface; and
a nanometer-size p-type crystal silicon that is disposed on the one surface of the silicon substrate and has the same crystal face orientation as the silicon substrate.

19. The crystal silicon element according to claim 18, further comprising:
a metal electrode; and
a transparent electrode that forms a pair of electrodes together with the metal electrode, wherein
the pair of electrodes sandwiches the p-type crystal silicon and the silicon substrate, and
the transparent electrode contacts directly the p-type crystal silicon so as to form an ohmic contact.

20. The crystal silicon element according to claim 18, wherein the resistivity of the silicon substrate is 10 mΩcm or less.

21. The crystal silicon element according to claim 18, wherein the p-type crystal silicon is doped with aluminum.

22. A crystal silicon element comprising:
a n-type single crystal silicon substrate that has one surface and the other surface opposite to the one surface;
a nanometer-size p-type crystal silicon that is disposed on the one surface of the silicon substrate and has the same crystal face orientation as the silicon substrate;
a transparent electrode that is formed on the one surface of the silicon substrate, the silicon substrate having the p-type crystal silicon disposed on the one surface; and
a metal electrode that is formed on the other surface of the silicon substrate.

23. The crystal silicon element according to claim 22, wherein
the p-type crystal silicon and the transparent electrode contact each other through an insulating film, and
a current flow passage is from the transparent electrode, through the insulating film, the p-type crystal silicon and the silicon substrate, to the metal electrode, the current flow passage being formed when a voltage is applied for carrier injection across two electrodes of the transparent electrode serving as an anode and the metal electrode serving as a cathode.

24. The crystal silicon element according to claim 22, wherein
the p-type crystal silicon and the transparent electrode directly contact each other, and
a current flow passage is from the transparent electrode, through the p-type crystal silicon and the silicon substrate, to the metal electrode, the current flow passage being formed when a voltage is applied for carrier injection across two electrodes of the transparent electrode serving as an anode and the metal electrode serving as a cathode.

25. A method for fabricating a crystal silicon element using silicon microcrystals, the method comprising:
a p-type crystal silicon disposing process that disposes a plurality of p-type crystal silicons that grows in a solid phase on one surface of the n-type single crystal silicon substrate, the plurality of p-type crystal silicons being nanometer-sized and having the same crystal face orientation as the silicon substrate;
a transparent electrode disposing process that disposes a transparent electrode on the one surface where the p-type crystal silicon is disposed; and
a metal electrode disposing process that disposes a metal electrode on the other surface of the silicon substrate.

26. The method according to claim 25, wherein the p-type crystal silicon disposing process comprises:
a forming process that forms a thin film of aluminum-silicon (Al—Si) on the silicon substrate;
a epitaxially-growing process that epitaxially grows in solid phase the p-type crystal silicon on the silicon substrate through heat treatment at a temperature not exceeding the melting point of the aluminum-silicon (Al—Si); and
a removing process that removes the thin film of aluminum-silicon (Al—Si).

27. A method for fabricating a crystal silicon element using silicon microcrystals, the method comprising:
a forming process that forms a thin film of aluminum-silicon (Al—Si) on one surface of a silicon substrate of a single crystal;
a epitaxially-growing process that epitaxially grows in solid phase a p-type crystal silicon on the silicon substrate through heat treatment in a temperature range not exceeding the melting point of the aluminum-silicon (Al—Si), but allowing solid phase epitaxial growth to proceed; and
a removing process that removes the thin film of aluminum-silicon (Al—Si).

28. The method according to claim 27, further comprising:
a transparent electrode disposing process that disposes a transparent electrode on the one surface of the silicon substrate; and
a metal electrode disposing process that disposes a metal electrode on the other surface of the silicon substrate.

29. A crystal silicon element comprising:
a single crystal silicon substrate that has a pair of surfaces; and
a plurality of quasi-columnar crystal silicons that are disposed on a principal surface of the single crystal silicon substrate, have the same crystal face orientation as the principal surface, and stand quasi-perpendicularly to the single crystal silicon substrate surface.

30. The crystal silicon element according to claim 29, further comprising:
a metal electrode; and
a transparent electrode that forms a pair of electrodes together with the metal electrode, wherein
the pair of electrodes sandwiches the quasi-columnar crystal silicons.

31. The crystal silicon element according to claim 30, wherein
the metal electrode is disposed on the other surface of the single crystal silicon substrate and has an ohmic contact with the single crystal silicon substrate, and
the transparent electrode is disposed on the upper surface of the quasi-columnar crystal silicons so as to contact the upper surface of the quasi-columnar crystal silicons.

32. The crystal silicon element according to claim 31, wherein the transparent electrode directly contacts the upper surface of the quasi-columnar crystal silicons so as to form a Schottky junction.

33. The crystal silicon element according to claim 31, wherein the transparent electrode contacts the upper face of the quasi-columnar crystal silicons through an insulating film easily tunnel-injected by carriers.

34. The crystal silicon element according to claim 31, wherein
the quasi-columnar crystal silicons have in the height direction a p-n junction with a p-type and n-type two-layered structure, and
the transparent electrode contacts directly any one of the p-type and the n-type layers positioned in the upper layer of the quasi-columnar crystal silicons so as to form an ohmic contact.

35. The crystal silicon element according to any one of claims 32 to 34, wherein
the bottom face of the quasi-columnar crystal silicons contacts directly the single crystal silicon substrate to form a homo-junction, and
at least the side face of the quasi-columnar crystal silicons is covered with an insulating film so as to be electrically insulated from the transparent electrode except the upper face of the quasi-columnar crystal silicons.

36. The crystal silicon element according to claim 29, wherein the upper face of the quasi-columnar crystal silicons has a crystal structure with a crystal face having at least any one of the orientations (100), (110), and (111).

37. A crystal silicon element comprising:
a single crystal silicon substrate that has a pair of surfaces;
a plurality of quasi-columnar crystal silicons that are disposed on a principal surface of the single crystal silicon substrate, have the same crystal face orientation as the principal surface, and stand quasi-perpendicularly to the single crystal silicon substrate surface;
a transparent electrode that is formed on the principal surface of the single crystal silicon substrate and has a contact with the upper face of the quasi-columnar crystal silicons, the single crystal silicon substrate having the quasi-columnar crystal silicons disposed on the principal surface; and
a metal electrode that is formed on the other surface opposite to the principal surface of the single crystal silicon substrate.

38. The crystal silicon element according to claim 37, wherein the quasi-columnar crystal silicons have a diameter of 4 nm or less and a column height 2 to 50 times of the diameter.

39. The crystal silicon element according to claim 37, wherein the quasi-columnar crystal silicons are controlled in size so as to emit visible monochromatic light or white light.

40. A method for fabricating a crystal silicon element using silicon microcrystals, the method comprising:
a quasi-columnar crystal silicons disposing process that disposes a plurality of quasi-columnar nanometer-size crystal silicons having the same crystal face orientation as a silicon substrate on a principal surface of the silicon substrate, the plurality of the quasi-columnar crystal silicons standing quasi-perpendicularly to the principal surface;
a transparent electrode disposing process that disposes a transparent electrode on the principal surface of the silicon substrate, the transparent electrode contacting the upper face of the quasi-columnar crystal silicons; and
a metal electrode disposing process that disposes a metal electrode on the other surface opposite to the principal surface of the silicon substrate.

41. The method according to claim 40, wherein the quasi-columnar crystal silicons disposing process comprises:
a thin film disposing process that disposes a thin film of aluminum on the principal surface of the silicon substrate;
a converting process that converts the thin film of aluminum into porous alumina having micropores with a uniform size through anodic oxidation;
a embedding process that embeds an inorganic material in the micropores of the porous alumina;
a removing process that selectively removes the porous alumina by etching; and
a quasi-columnar protrusions disposing process that disposes quasi-columnar protrusions by etching the principal surface of the silicon substrate using the inorganic material as a mask.

42. The method according to claim 40, wherein the quasi-columnar crystal silicons disposing process comprises:
a organic film disposing process that disposes an organic film of a block copolymer on the principal surface of the silicon substrate;
a heating process that heats the organic film to achieve phase separation;
a etching process that selectively etches the organic film to form micropores in a uniform size;
a embedding process that embeds an inorganic material in the micropores of the organic film; and
a etching process that etches the organic film and the principal surface of the silicon substrate using the inorganic material as a mask to form quasi-columnar protrusions.

43. The method according to claim 41 or claim 42, further comprising a oxidizing process that oxidizes the principal surface of the silicon substrate except the upper face of the quasi-columnar protrusions to control the diameter of the quasi-columnar protrusions and to dielectrically isolate the silicon substrate and the side face of the quasi-columnar crystal silicons from the transparent electrode.
